(19) United States
(12) Patent Application Publication
(10) Pub. No.: US 2026/0089835 A1
(43) Pub. Date: Mar. 26, 2026

(54) PRINTED CIRCUIT BOARD

(71) Applicant: Samsung Electronics Co., Ltd., Suwon-si (KR)

(72) Inventor: Hyejin KIM, Suwon-si (KR)

(73) Assignee: Samsung Electronics Co., Ltd., Suwon-si (KR)

(21) Appl. No.: 19/086,403

(22) Filed: Mar. 21, 2025

(30) Foreign Application Priority Data
Sep. 23, 2024 (KR) 10-2024-0128388

(51) Int. Cl. H05K 1/02; G02B 6/12; G02B 6/125; H05K 1/03

(52) U.S. Cl. CPC H05K 1/0274; G02B 6/12004; G02B 6/125; H05K 1/0201; H05K 1/0306; H05K 2201/017; H05K 2201/037; H05K 2201/066; H05K 2201/09481; H05K 2201/09509; H05K 2201/09827; H05K 2201/09985

(57) ABSTRACT

A printed circuit board that includes a core substrate including a core layer, an upper glass layer on a surface of the core layer, and a lower glass layer on another surface of the core layer; an optical waveguide including at least a portion between the upper glass layer and the lower glass layer, the optical waveguide including a reflection layer on at least a portion of an inner wall of the optical waveguide; a first pad on the core substrate, the first pad being connected to the optical waveguide; a second pad on the core substrate, the second pad being spaced apart from the first pad, and the second pad being connected to the optical waveguide; and a heat emission layer contacting at least a portion of each of the first pad and the second pad.

### CROSS-REFERENCE TO RELATED APPLICATIONS

This application claims the benefit of Korean Patent Application No. 10-2024-0128388, filed on Sep. 23, 2024, in the Korean Intellectual Property Office, the disclosure of which is incorporated herein by reference in its entirety.

### BACKGROUND

The present disclosure relates to printed circuit boards.

Printed circuit boards may have metallic circuits including copper and may connect various electronic element components to the metallic circuits to transmit electrical signals of the electronic element components. However, when a metallic circuit is used, a transmission speed may be slower than a speed at which high-performance and highly integrated electronic elements process a signal, which may affect product performance and/or reliability.

In order to improve a metallic circuit scheme, in a light transmitting printed circuit board in which an optical waveguide is installed, multiple bent optic fibers are placed in the optical waveguide, and an electrical signal is transmitted in a form of light has been adopted. However, since the multiple bent optic fibers are disposed in the optical waveguide, diffuse reflection occurs along a bent path, and the transmitted signal may be distorted. Also, local heat may be generated due to light diffusely reflected on the bent path, and a structure of the optical waveguide may be deformed due to the heat, so that signal distortion and light loss may occur.

Recently, further diversification, higher performance, and higher integration of electronic element components have been accomplished by artificial intelligence or the like, and a data transmission amount between electronic element components has been greatly increased. When an electrical signal having a large amount of data is transmitted in the form of light, heat may be generated in the optical waveguide, and there may be a possibility of losing a portion of the data due to the heat. Thus, a method of transmitting increased data and appropriately processing heat generated during data transmission may be advantageous.

### SUMMARY

Some example embodiments of the present disclosure provide a printed circuit board that effectively transmits an electrical signal having a large amount of data by reducing (and/or minimizing) occurrence of signal distortion, and/or limiting and/or preventing deformation due to heat by rapidly dispersing the heat even when the heat is generated.

However, the objectives achieved by some example embodiments of the present disclosure are not limited to the objectives described above and other objects may be clearly understood by those skilled in the art from the following description of some example embodiments.

Some example embodiments provide a printed circuit board that includes a core substrate including a core layer, an upper glass layer on a surface of the core layer, and a lower glass layer on another surface of the core layer; an optical waveguide including at least a portion between the upper glass layer and the lower glass layer, the optical waveguide including a reflection layer on at least a portion of an inner wall of the optical waveguide; a first pad on the core substrate, the first pad being connected to the optical waveguide; a second pad on the core substrate, the second pad being spaced apart from the first pad, and the second pad being connected to the optical waveguide; and a heat emission layer contacting at least a portion of each of the first pad and the second pad.

Some example embodiments further provide a printed circuit board that includes a core substrate including a core layer, an upper glass layer on a surface of the core layer, and a lower glass layer on another surface of the core layer, the core layer including a dielectric; an optical waveguide including at least a portion between the upper glass layer and the lower glass layer, the optical waveguide including a reflection layer on at least a portion of an inner wall of the optical waveguide; a first pad on the core substrate, the first pad being connected to the optical waveguide; a second pad on the core substrate, the second pad being spaced apart from the first pad, and the second pad being connected to the optical waveguide; and a heat emission layer contacting at least a portion of each of the first pad and the second pad. The at least a portion of the inner wall of the optical waveguide has an average surface roughness less than or equal to 50 nanometers.

Some example embodiments still further provide a printed circuit board that includes a core substrate including a core layer, an upper glass layer on a surface of the core layer, and a lower glass layer on another surface of the core layer, the core layer including a dielectric; an optical waveguide including at least a portion between the upper glass layer and the lower glass layer, the optical waveguide including a reflection layer on at least a portion of an inner wall of the optical waveguide; a first pad on the core substrate, the first pad being connected to the optical waveguide; a second pad on the core substrate, the second pad being spaced apart from the first pad, and the second pad being connected to the optical waveguide; and a heat emission layer contacting at least a portion of each of the first pad and the second pad. When viewed in a first direction perpendicular to an upper surface of the core substrate, the optical waveguide includes a first area overlapping the first pad, a second area overlapping the second pad, and a third area connecting the first area and the second area. The first area and the second area are side by side and extend parallel to the first direction. The third area extends parallel to a second direction, the second direction being parallel to the upper surface of the core substrate and the second direction crossing the first direction. The at least a portion of the inner wall of the optical waveguide has an average surface roughness less than or equal to 50 nanometers. A total reflectance of the at least a portion of the inner wall of the optical waveguide for an ultraviolet ray is less than or equal to 10%. A specular reflectance of the at least a portion of the inner wall of the optical waveguide for the ultraviolet ray is less than or equal to 10%. A diffuse reflectance of the at least a portion of the inner wall of the optical waveguide for the ultraviolet ray is less than or equal to 3%.

Additional aspects of some example embodiments will be set forth in part in the description which follows and, in part, will be apparent from the description.

According to some example embodiments, it is possible to provide a printed circuit board that effectively transmits an electrical signal having a large amount of data by reducing (and/or minimizing) occurrence of signal distortion, and/or limiting and/or preventing deformation due to heat by rapidly dispersing the heat even when the heat is generated.

Effects of the some example embodiments of the present disclosure are not limited to those described above and other effects may be apparent to those skilled in the art from the following description of the accompanying claims.

### BRIEF DESCRIPTION OF THE DRAWINGS

The above and/or other aspects, features, and advantages of the inventive concepts will become apparent and more readily appreciated from the following description of some example embodiments, taken in conjunction with the accompanying drawings of which:

FIGS. 1, 2, 3, 4 and 5 are cross-sectional diagrams schematically illustrating a printed circuit board according to some example embodiments of the present disclosure;

FIGS. 6, 7, 8 and 9 are cross-sectional diagrams illustrating disposition of a heat emission layer according to some example embodiments of the present disclosure;

FIGS. 10, 11, 12 and 13 are cross-sectional diagrams illustrating disposition of a heat emission layer according to some example embodiments of the present disclosure;

FIGS. 14, 15, 16, 17, 18 and 19 are cross-sectional diagrams illustrating a process of manufacturing a printed circuit board according to some example embodiments of the present disclosure;

FIGS. 20, 21, 22, 23, 24 and 25 are cross-sectional diagrams illustrating a process of manufacturing a printed circuit board with different disposition of a heat emission layer according to some example embodiments of the present disclosure; and

FIGS. 26, 27, 28, 29, 30 and 31 are a cross-sectional diagrams illustrating a process of manufacturing a printed circuit board with different disposition of a heat emission layer according to some example embodiments of the present disclosure.

### DETAILED DESCRIPTION

In the following description, terms or words used in the present disclosure and the accompanying claims are not to be limited to general definitions or dictionary definitions. The terms and words are to be construed under a principle that an inventor may appropriately define a concept of a term in order to describe the inventive concepts in the best way. Some example embodiments described in the present disclosure and configurations illustrated in the accompanying drawings are representative of some example embodiments and do not represent all of the technical spirit of the present disclosure. Thus, it should be understood that various equivalents and modifications may replace some example embodiments and configurations of the present disclosure.

The same reference numerals or symbols illustrated in the accompanying drawings represent components or elements performing the same or substantially identical functions. For convenience for description and understanding, some example embodiments different from each other may be described with the same reference numerals or symbols. For example, although a plurality of drawings illustrate elements having the same reference numeral, the plurality of drawings do not limit the some example embodiments.

In the present disclosure, when an element is described as being “directly on” or “in contact with” another element, it may be understood that the element is in direct contact with or connected to the other element or that still another element is absent between them.

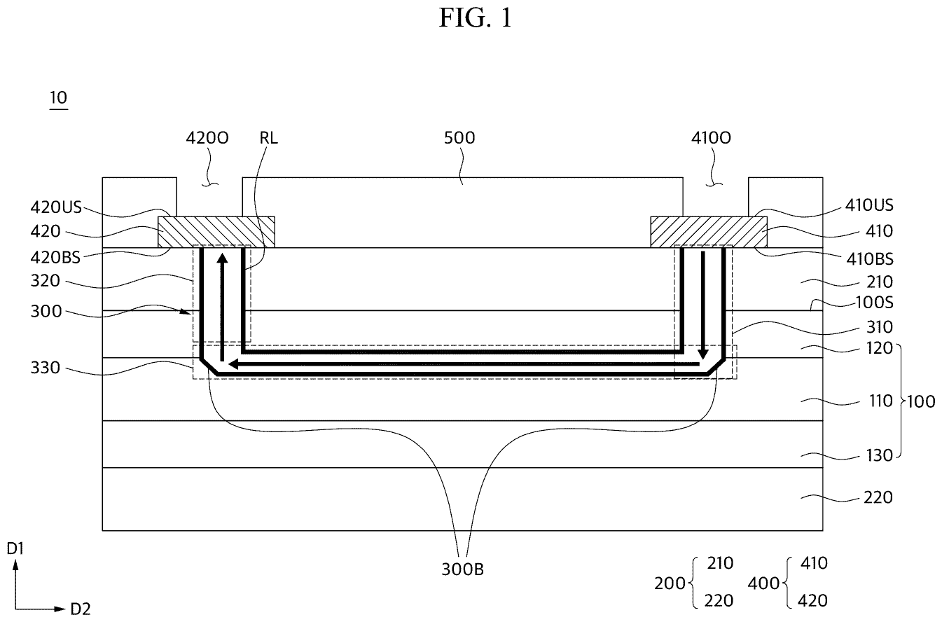

Also, in the present disclosure, when an element is described as being “above” or “on an upper surface of” another element, it may be understood that the element is present over the other element in a vertical direction. For example, the element may be understood as being over the other element in a direction D1 in a diagram (e.g., FIG. 1). They may be in direct contact or directly connected, but it may be understood that still another element is present between them. This may be similarly applied to a case in which an element is described as being “over”another element.

In the present disclosure, when an element is described as being “below” or “on lower surface of” another element, it may be understood that the element is present under the other element in a vertical direction. For example, the element may be understood as being under the other element in a direction D1 in a diagram (e.g., FIG. 1). They may be in direct contact or directly connected, but it may be understood that still another element is present between them. This may be similarly applied to a case in which an element is described as being “under”another element.

Other similar expression for describing a relationship between positions of elements may be construed similarly to the above.

In the following descriptions, terms in a singular form include terms in a plural form unless an apparently and contextually conflicting description is present. Terms such as “including” or “comprising” is to indicate that a feature, a number, an operation, an action, an element, a component, or a combination thereof is present. It should be understood that the terms are not to exclude in advance a possibility that one or more other features, numbers, operations, actions, elements, components, or combinations thereof may be present or added.

It should be noted in advance that an expression such as an upper side, an upper surface, a lower side, a lower surface, a side surface, a front surface, or a rear surface is based on directions illustrated in the drawings and that the expression may be changed when a direction of a corresponding object is changed.

Terms including an ordinal number such as “first” or “second” used in the present specification and claims may be used to distinguish elements. Such an ordinal number is used to contextually distinguish identical or similar elements from each other. Meanings of the terms may not be limited by use of the ordinal number. For example, a use order, a disposition order, or the like of elements with such an ordinal number may not be limitedly construed by the number. Ordinal numbers may be substituted with each other.

A physical property described in the present disclosure may be measured at normal temperature and pressure unless specifically limited. For example, a normal temperature in the present disclosure may be non-manipulated natural temperature within a range from 10 degrees Celsius (° C.) to 30° C., from 20° C. to 28° C., or from 22° C. to 26° C. In some example embodiments, the normal temperature may be 25° C. The normal pressure in the present disclosure may be non-manipulated natural pressure within a range from 700 millimeters of mercury (mmHg) to 800 mmHg or from 720 mmHg to 780 mmHg. In some example embodiments, the normal pressure may be 760 mmHG.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

The following terms such as, for example, “at least one of A, B, and C” and similar language (e.g., “at least one selected from the group consisting of A, B, and C”) when used in the specification may be construed as A only, B only, C only, or any combination of two or more of A, B, and C, such as, for instance, ABC, AB, BC, and AC.

FIGS. 1 through 5 are cross-sectional diagrams schematically illustrating a printed circuit board according to some example embodiments of the present disclosure. In some example embodiments, a printed circuit board 10 may include a core substrate 100, an optical waveguide 300, a pad 400, and a heat emission layer 500.

In the present disclosure, a first direction D1 may be a direction perpendicular to a surface 100S of the core substrate, and a second direction D2 may be a direction parallel to the surface 100s of the core substrate and crossing the first direction D1. Referring to FIG. 1, in some example embodiments, the first direction D1 and the second direction D2 may cross, and for example, the first direction D1 and the second direction D2 may be perpendicular to each other.

In some example embodiments, the core substrate 100 may include a core layer 110, an upper glass layer 120 disposed on a surface of the core layer 110, and a lower glass layer 130 disposed on another surface of the core layer 110. In some example embodiments, each of the upper glass layer 120 and the lower glass layer 130 may have a transmittance for an ultraviolet ray greater than or equal to 80%, 85%, or 90%. In some example embodiments, the transmittance may be measured through ultraviolet-visible ray spectroscopy (UV-Vis spectroscopy), and for example, may be for light having a wavelength of approximately 302 nanometers (nm). In some example embodiments, the transmittance may be measured through a sample having a thickness, for example, less than or equal to 1 millimeter (mm). In some example embodiments, each of the upper glass layer 120 and the lower glass layer 130 may include silicon oxide. Through this, the transmittance within the above-described range may be implemented.

In some example embodiments, the core layer 110 is not specifically limited, but may include a dielectric. In some example embodiments, the dielectric may include, for example, one or more selected from a group including silicon oxide, silicon nitride, and silicon oxynitride. In some example embodiments, when the core layer 110 includes the dielectric, destruction of the upper glass layer 120 and the lower glass layer 130 may be reduced (and/or minimized) at a time of forming the optical waveguide 300.

In some example embodiments, at least a portion of the optical waveguide 300 may be disposed between the upper glass layer 120 and the lower glass layer 130. In some example embodiments, at least a portion of the optical waveguide 300 may be disposed in the upper glass layer 120. In some example embodiments, at least a portion of the optical waveguide 300 may be disposed in each of the upper glass layer 120 and the core layer 110. In some example embodiments, when the at least a portion of the optical waveguide 300 is disposed in the core layer 110, the destruction of the upper glass layer 120 and the lower glass layer 130 may be reduced (and/or minimized) at the time of forming the optical waveguide 300.

In some example embodiments, the optical waveguide 300 may be an empty space. In some example embodiments, the optical waveguide 300 may be implemented by processing a portion of the core substrate 100 through drilling, laser work, or the like.

In some example embodiments, the optical waveguide 300 may include a reflection layer RL formed to at least a portion of an inner wall. In some example embodiments, the reflection layer RL may include a material that reflects light. In some example embodiments, the material reflecting the light may include, for example, a metal, and the metal may include one or more selected from a group including aluminum (Al), mercury (Hg), gold (Au), silver (Ag), and copper (Cu). However, thus is merely an example. In some example embodiments, the reflection layer RL may be formed through deposition. For example, the deposition may be performed as one or more of chemical vapor deposition (CVD), physical vapor deposition (PVD), atomic layer deposition (ALD), and the like.

In some example embodiments, the at least a portion of the inner wall of the optical waveguide 300 including the reflection layer RL formed to the inner wall may have an average surface roughness (Ra) less than or equal to 50 nm, 45 nm, 40 nm, 35 nm, 30 nm, 25 nm, 20 nm, 15 nm, or 10 nm. In some example embodiments, the average surface roughness may be an arithmetic average surface roughness and measured according to KS B ISO4287 standard. In some example embodiments, the average surface roughness may be measured through a sample manufactured by stacking, with a sputtering scheme, a metal on a surface of a glass layer used for the upper glass layer 120 and the lower glass layer 130. In some example embodiments, the optical waveguide 300 may have the average surface roughness within the above described range. Through this, signal distortion due to diffuse reflection or scattering of light may be reduced (and/or minimized).

In some example embodiments, the at least a portion of the inner wall of the optical waveguide 300 including the reflection layer RL formed to the inner wall may have a total reflectance less than or equal to 10%, 9.5%, 9%, 8.5%, 8%, 7.5%, 7%, 6.5%, 6%, 5.5%, 5%, 4.5%, or 4%. In some example embodiments, the total reflectance may be measured through the ultraviolet-visible ray spectroscopy, may be a combination of specular reflectance and diffuse reflectance, and for example, may be for the light having the wavelength of approximately 302 nm. In some example embodiments, the total reflectance may be measured through the sample manufactured by stacking, with the sputtering scheme, the metal on the surface of the glass layer used for the upper glass layer 120 and the lower glass layer 130. In some example embodiments, the optical waveguide 300 may have the total reflectance within the above described range. Through this, the signal distortion due to the diffuse reflection or the scattering of light may be reduced (and/or minimized).

In some example embodiments, the at least a portion of the inner wall of the optical waveguide 300 including the reflection layer RL formed to the inner wall may have a specular reflectance less than or equal to 10%, 9.5%, 9%, 8.5%, 8%, 7.5%, 7%, 6.5%, 6%, 5.5%, 5%, 4.5%, 4%, 3.5%, or 3%. In some example embodiments, the specular reflectance may be measured through the ultraviolet-visible ray spectroscopy, and for example, may be for the light having the wavelength of approximately 302 nanometers. In some example embodiments, the specular reflectance may be measured through the sample manufactured by stacking, with the sputtering scheme, the metal on the surface of the glass layer used for the upper glass layer 120 and the lower glass layer 130. In some example embodiments, the optical waveguide 300 may have the specular reflectance within the above described range. Through this, the signal distortion due to the diffuse reflection or the scattering of light may be reduced (and/or minimized).

In some example embodiments, the at least a portion of the inner wall of the optical waveguide 300 including the reflection layer RL formed to the inner wall may have a diffuse reflectance less than or equal to 3%, 2.8%, 2.6%, 2.4%, 2.2%, 2%, 1.8%, 1.6%, 1.4%, 1.2%, or 1%. In some example embodiments, the diffuse reflectance may be measured through the ultraviolet-visible ray spectroscopy, and for example, may be for the light having the wavelength of approximately 302 nanometers. In some example embodiments, the diffuse reflectance may be measured through the sample manufactured by stacking, with the sputtering scheme, the metal on the surface of the glass layer used for the upper glass layer 120 and the lower glass layer 130. In some example embodiments, the optical waveguide 300 may have a diffuse reflectance within the above described range. Through this, the signal distortion due to the diffuse reflection or the scattering of light may be reduced (and/or minimized). For example, the diffuse reflection or the scattering of light which causes the signal distortion may have a close relationship with the diffuse reflectance, and although an electrical signal having a large amount of data is transmitted in a form of light, occurrence of the signal distortion may be reduced (and/or minimized) through the optical waveguide 300 having the diffuse reflectance within the above-described range.

In some example embodiments, a plurality of pads 400 may be present, or the pad 400 may include a first pad 410 and a second pad 420. In some example embodiments, the first pad 410 may be disposed on the core substrate 100 and connected to the optical waveguide 300. In some example embodiments, the second pad 420 may be disposed on the core substrate 100, disposed to be spaced apart from the first pad 410, and connected to the optical waveguide 300.

In some example embodiments, each of the first pad 410 and the second pad 420 may independently include a conductive material. In some example embodiments, the conductive material may include one or more selected from a group including doped polysilicon, a metal, a conductive metallic nitride, a conductive metallic silicide, and a conductive metallic oxide. In some example embodiments, the metal may include one or more selected from a group including aluminum (Al), copper (Cu), titanium (Ti), tantalum (Ta), rubidium (Rb), tungsten (W), molybdenum (Mo), platinum (Pt), iridium (Ir), nickel (Ni), gold (Au), silver (Ag), and cobalt (Co). In some example embodiments, the conductive metallic nitride may include one or more selected from titanium aluminide (TiAl) and titanium aluminum nitride (TiAlN). In some example embodiments, the conductive metallic silicide may include one or more selected from a group including titanium silicide (TiSi), titanium silicon nitride (TiSiN), tantalum silicide (TaSi), tantalum silicon nitride (TaSiN), rubidium titanium nitride (RbTiN), nickel silicide (NiSi), and cobalt silicide (CoSi). In some example embodiments, the conductive metallic oxide may include one or more selected from iridium oxide (IrOx) and rubidium oxide (RbOx).

In some example embodiments, the first pad 410 and the second pad 420 may be disposed on an identical plane. Here, “on an identical plane” may mean “on the same or on substantially identical planes”. In some example embodiments, when viewed in the second direction D2, at least portions of the first pad 410 and the second pad 420 may overlap.

In some example embodiments, when viewed in the first direction D1, the optical waveguide 300 may include a first area 310 overlapping the first pad 410, a second area 320 overlapping the second pad 420, and a third area 330 connecting the first area 310 and the second area 320.

In some example embodiments, the first area 310 and the second area 320 may be disposed side by side parallel to the first direction D1. Through this, when the electrical signal having the data is transmitted in the form of the light, the signal distortion may be reduced (and/or minimized) by simplifying a light path.

In some example embodiments, the third area 330 may be disposed parallel to the second direction D2. Through this, when the electrical signal having the data is transmitted in the form of the light, the signal distortion may be reduced (and/or minimized) by simplifying the light path.

In some example embodiments, the optical waveguide 300 may include a bent portion 300B disposed between the first area 310 and the third area 330 and between the second area 320 and the third area 330. In some example embodiments, when the light is transmitted from the first area 310 to the second area 320, the bent portion 300B may change a path of the light so that the light is transmitted from the first area 310 to the third area 330 and transmitted from the third area 330 to the second area 320. In some example embodiments, when the light is transmitted from the second area 320 to the first area 310, the bent portion 300B may change the path of the light so that the light is transmitted from the second area 320 to the third area 330 and transmitted from the third area 330 to the first area 310. In some example embodiments, the bent portion 300B may change the path of the light which is incident from the first area 310 or the second area 320, so that the light is not in contact with an inner wall of the third area 330. In some example embodiments, the bent portion 300B may be bent at a desired (and/or alternatively predetermined) angle to the surface 100S of the core substrate 100, and the desired (and/or alternatively predetermined) angle may be designed in consideration of the above described path of the light.

In some example embodiments, the heat emission layer 500 may be in contact with at least a portion of the pad 400. In some example embodiments, the heat emission layer 500 may be in contact with at least a portion of each of the first pad 410 and the second pad 420.

In some example embodiments, the heat emission layer 500 may not be specifically limited, but may include a resin component for convenience for manufacturing. In some example embodiments, the resin component may be a curing resin. For example, the resin component may be a material that is present as a viscous composition before forming the heat emission layer 500 and cures in a desired (and/or alternatively predetermined) environment. In some example embodiments, the resin component may be an actinic radiation-curable type, a moisture-curable type, a thermosetting type, or a room temperature-curable type. In some example embodiments, any materials such as for example, an acrylic resin, an epoxy-based resin, a urethane-based resin, an olefin-based resin, an ethylene vinyl acetate (EVA)-based resin, a silicone-based resin, or the like may be used for the curing resin.

In some example embodiments, the heat emission layer 500 may include a filler component dispersed in the resin component. In some example embodiments, as long as a material may secure heat conductivity and an insulating property of the heat emission layer 500, the material may be used as the filler component without limitation. In some example embodiments, the filler component may include one or more selected from a group including a metallic hydroxide such as aluminium hydroxide (Al(OH)3), magnesium hydroxide (Mg(OH)2), calcium hydroxide (Ca(OH)2), boehmite (AlOOH), and hydromagnesite, a metallic oxide such as zinc oxide (ZnO), beryllium oxide (BeO), magnesia, and alumina (Al2O3), a nitride such as aluminum nitride (AlN), boron nitride (BN), and silicon nitride (Si3N4), and silicon carbide (SiC).

In some example embodiments, the heat emission layer 500 may have a heat conductivity greater than or equal to 0.5 watt per meter-Kelvin (W/m·K), 0.6 W/m·K, 0.7 W/m·K, 0.8 W/m·K, 0.9 W/m·K, 1 W/m·K, 1.1 W/m·K, 1.2 W/m·K, 1.3 W/m·K, 1.4 W/m·K, 1.5 W/m·K, 1.6 W/m·K, 1.7 W/m·K, 1.8 W/m·K, 1.9 W/m·K, or 2 W/m·K. In some example embodiments, the heat conductivity may be measured according to ASTM D 5470 standard (a measurement type is “through plane”) by using a sample having a diameter of 50 mm and a thickness of 4 mm. In some example embodiments, the heat emission layer 500 may include 70 weight percent or more, 75 weight percent or more, 80 weight percent or more, or 85 weight percent or more of the filler component compared to a total weight. Through this, the above described heat conductivity may be implemented.

In some example embodiments, at least a portion of the heat emission layer 500 may surround at least a portion of an upper surface 410US of the first pad and an upper surface 420US of the second pad. In some example embodiments, at least a portion of the heat emission layer 500 may surround at least a portion of a lower surface 410BS of the first pad and a lower surface 420BS of the second pad.

In some example embodiments, at least a portion of the heat emission layer 500 may include (e.g., define therein) a first exposure part 410O that is formed by penetrating the heat emission layer 500 and exposes at least a portion of the upper surface 410US of the first pad and a second exposure part 420O that is formed by penetrating the heat emission layer 500 and exposes at least a portion of the upper surface 420US of the second pad.

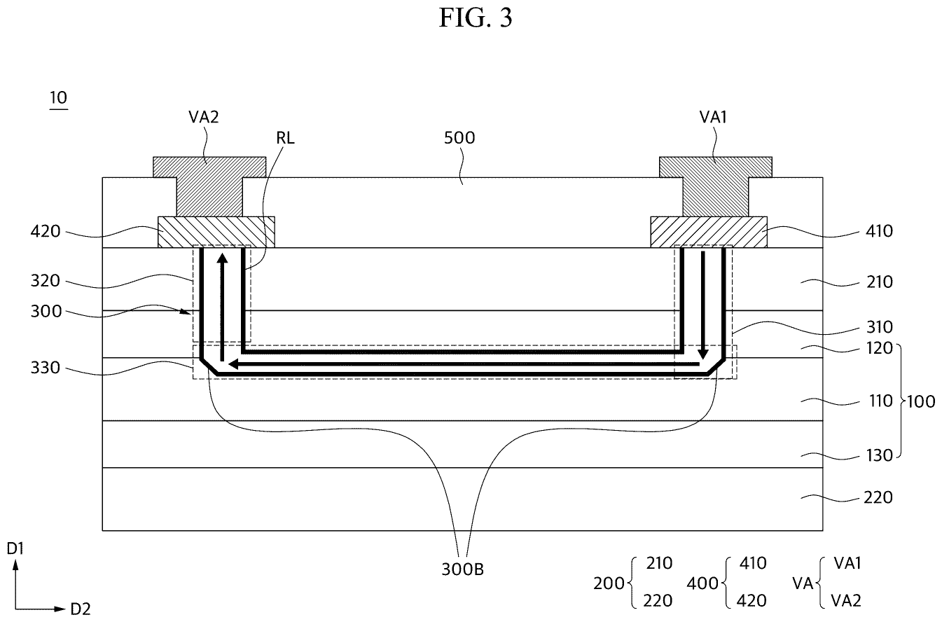

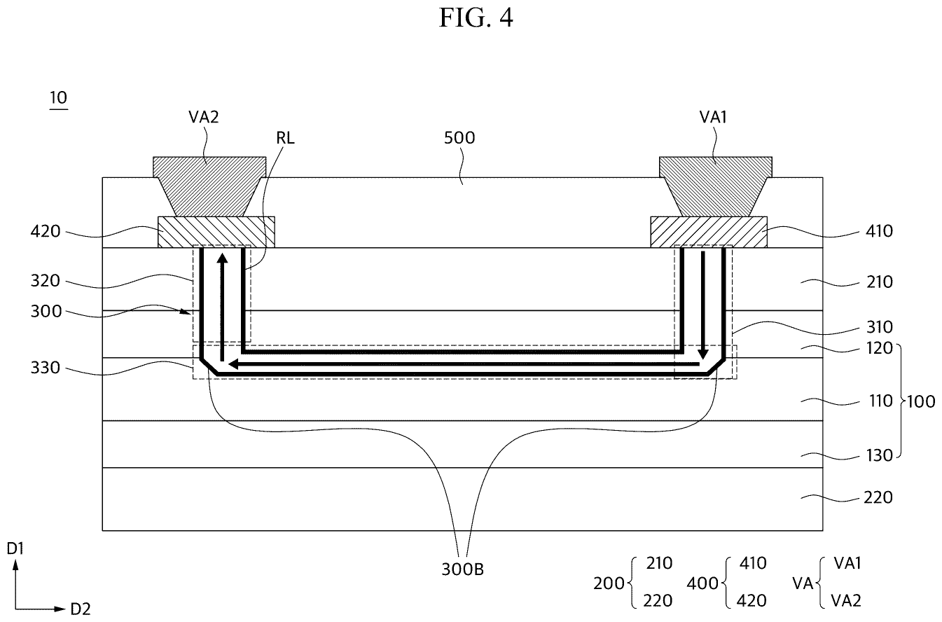

In some example embodiments, the printed circuit board 10 may include a via VA (e.g., see FIGS. 3 and 4) electrically connected to the pad 400. In some example embodiments, the via VA may include a conductive material. In some example embodiments, the conductive material may include one or more selected from a group including doped polysilicon, a metal, a conductive metallic nitride, a conductive metallic silicide, and a conductive metallic oxide. In some example embodiments, the metal may include one or more selected from a group including aluminum (Al), copper (Cu), titanium (Ti), tantalum (Ta), rubidium (Rb), tungsten (W), molybdenum (Mo), platinum (Pt), iridium (Ir), nickel (Ni), gold (Au), silver (Ag), and cobalt (Co). In some example embodiments, the conductive metallic nitride may include one or more selected from titanium aluminide (TiAl) and titanium aluminum nitride (TiAlN). In some example embodiments, the conductive metallic silicide may include one or more selected from a group including titanium silicide (TiSi), titanium silicon nitride (TiSiN), tantalum silicide (TaSi), tantalum silicon nitride (TaSiN), rubidium titanium nitride (RbTiN), nickel silicide (NiSi), and cobalt silicide (CoSi). In some example embodiments, the conductive metallic oxide may include one or more selected from iridium oxide (IrOx) and rubidium oxide (RbOx). In some example embodiments, the via VA may include a first via VA1 disposed to the first exposure part 410O and electrically connected to the first pad 410 and a second via VA2 disposed to the second exposure part 420O and electrically connected to the second pad 420. In some example embodiments, each of the first via VA1 and the second via VA2 may independently include the above described conductive material.

In some example embodiments, a width of the first exposure part 410O may gradually increase along the second direction D2 away from the first pad 410 in the first direction D1. In some example embodiments, a width of the second exposure part 420O along the second direction D2 may gradually increase away from the second pad 420 in the first direction D1. In some example embodiments, each of the first exposure part 410O and the second exposure part 420O may independently include a sloped surface.

In some example embodiments, at least a portion of the heat emission layer 500 may surround at least a portion of an outer wall of the optical waveguide 300. Through this, a structure of the optical waveguide 300 may be limited and/or prevented from being deformed due to heat or the like.

In some example embodiments, the printed circuit board 10 may include an insulation layer 200 disposed on the core substrate 100. In some example embodiments, the insulation layer 200 may include a first insulation layer 210 disposed on a surface of the core substrate 100 and a second insulation layer 220 disposed on another surface of the core substrate 100. In some example embodiments, the first insulation layer 210 and the second insulation layer 220 are not specifically limited, but each may independently include one or more selected from a group including silicon oxide, silicon nitride, and silicon oxynitride. In some example embodiments, the first insulation layer 210 may be disposed on the upper glass layer 120, and the second insulation layer 220 may be disposed on the lower glass layer 130.

In some example embodiments, at least a portion of the optical waveguide 300 may be disposed in the first insulation layer 210. In some example embodiments, at least a portion of the optical waveguide 300 may be disposed between the first insulation layer 210 and the second insulation layer 220.

Referring to FIG. 1, in some example embodiments, the heat emission layer 500 may include the first exposure part 410O that is formed by penetrating the heat emission layer 500 and that exposes the at least a portion of the upper surface 410US of the first pad, and the second exposure part 420O that is formed by penetrating the heat emission layer 500 and that exposes the at least a portion of the upper surface 420US of the second pad. In some example embodiments, the at least a portion of the heat emission layer 500 may surround the at least a portion of the upper surface 410US of the first pad and the upper surface 420US of the second pad. In an some example embodiments, the heat emission layer 500 may rapidly disperse heat generated in the optical waveguide 300 to reduce (and/or minimize) deformation of the optical waveguide 300 due to the heat. Through this, the printed circuit board 10 may effectively transfer the electrical signal having the large amount of the data in the form of the light.

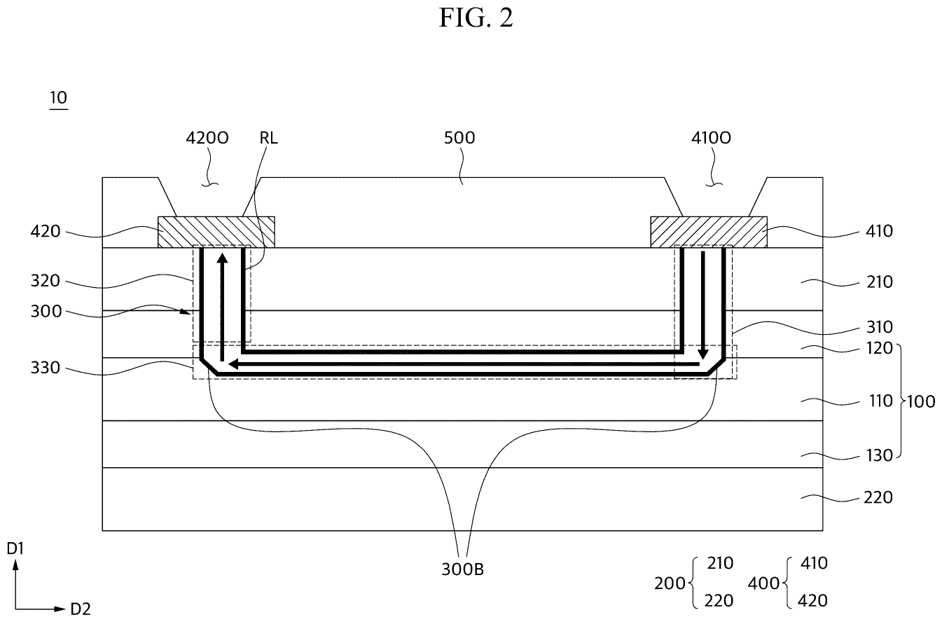

Referring to FIG. 2, in some example embodiments, the width of the first exposure part 410O along the second direction D2 may gradually increase away from the first pad 410 in the first direction D1, and the width of the second exposure part 420O along the second direction D2 may gradually increase away from the second pad 420 in the first direction D1. In some example embodiments, each of the first exposure part 410O and the second exposure part 420O may independently include the sloped surface.

Referring to FIGS. 3 and 4, in some example embodiments, the printed circuit board 10 may include the via VA including the first via VA1 disposed in the first exposure part 410O and electrically connected to the first pad 410, and the second via VA2 disposed to the second exposure part 420O and electrically connected to the second pad 420. In some example embodiments, a shape of each of the first via VA1 and the second via VA2 may be determined according to a shape of the first exposure part 410O and a shape of the second exposure part 420O.

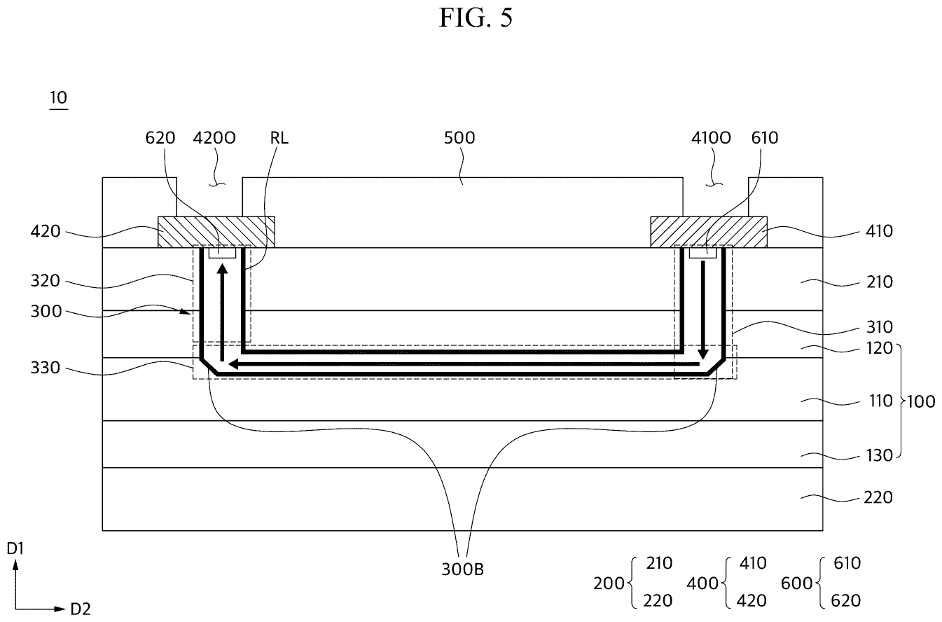

Referring to FIG. 5, in some example embodiments, the printed circuit board 10 may include an optical device 600. In some example embodiments, the optical device 600 may be disposed on the pad 400. In some example embodiments, the optical device 600 may include a first optical device 610 disposed on the first pad 410 and a second optical device 620 disposed on the second pad 420.

In some example embodiments, referring to FIG. 5, the first optical device 610 may be a light emitting element, and the second optical device 620 may be a light receiving element. For example, light generated by the first optical device 610 which is the light emitting element may pass through the first area 310, may be reflected to the third area 330 through the bent portion 300B to pass through the third area 330, and may be reflected to the second area 320 through the bent portion 300B to be incident on the second optical device 620 which is the light receiving element, so that the data may be transmitted.

In some example embodiments, unlike the above description, the first optical device 610 may be the light receiving element, and the second optical device 620 may be the light emitting element. For example, light generated by the second optical device 620 which is the light emitting element may pass through the second area 320, may be reflected to the third area 330 through the bent portion 300B to pass through the third area 330, and may be reflected to the first area 310 through the bent portion 300B to be incident on the first optical device 610 which is the light receiving element, so that the data may be transmitted.

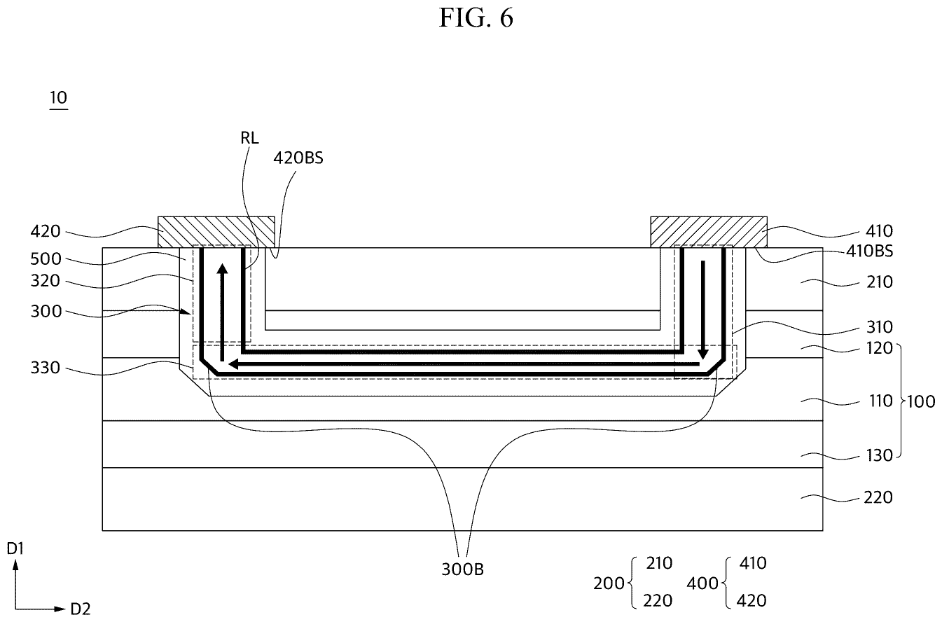

FIGS. 6 through 9 are cross-sectional diagrams illustrating disposition of the heat emission layer 500 according to some example embodiments of the present disclosure.

In some example embodiments, at least a portion of the heat emission layer 500 may surround a portion of the lower surface 410BS of the first pad and the lower surface 420BS of the second pad. In some example embodiments, at least a portion of the heat emission layer 500 may surround at least a portion of an outer wall of the optical waveguide 300. Through this, a structure of the optical waveguide 300 may be limited and/or prevented from being deformed due to heat or the like.

Referring to FIG. 6, the heat emission layer 500 may surround the outer wall of the optical waveguide 300 while surrounding the portion of the lower surface 410BS of the first pad and the portion of the lower surface 420BS of the second pad. For example, the heat emission layer 500 may surround the outer wall of the optical waveguide 300 at a portion of an area of the core substrate 100 which is surrounded by the first area 310, the second area 320, and the third area 330 and may also surround the outer wall of the optical waveguide 300 at a portion of the structure between the core substrate 100 and the pad 400 (e.g., pads 410 and 420). For example, the heat emission layer 500 may surround all of the outer wall of the optical waveguide. Through this, the structure of the optical waveguide 300 may be limited and/or prevented from being deformed due to the heat or the like.

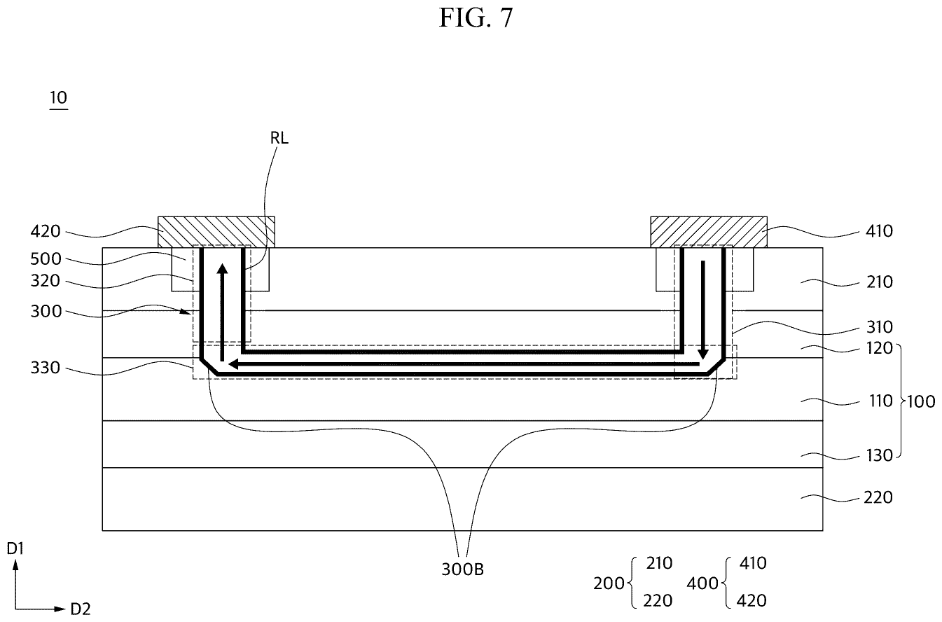

Referring to FIG. 7, the heat emission layer 500 may surround a portion of the outer wall of the optical waveguide 300 while surrounding a portion of the lower surface 410BS of the first pad and the lower surface 420BS of the second pad. For example, the heat emission layer 500 may surround a portion of the optical waveguide 300 at the first area 310 adjacent to the first pad 410 and a portion of the optical waveguide 300 at the second area 320 adjacent the second pad 420. Through this, the structure of the optical waveguide 300 may be limited and/or prevented from being deformed due to the heat or the like.

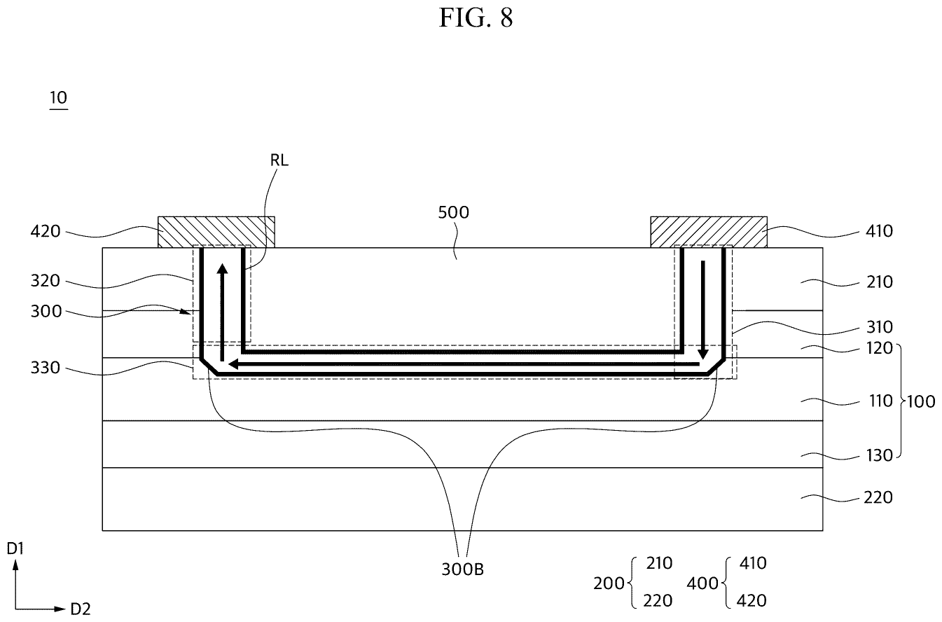

Referring to FIG. 8, while surrounding a portion of the lower surface 410BS of the first pad and the lower surface 420BS of the second pad, the heat emission layer 500 may be disposed at and fill the portion of the area of the core substrate 100 which is surrounded by the first area 310, the second area 320, and the third area 330 of the optical waveguide 300. Through this, the structure of the optical waveguide 300 may be limited and/or prevented from being deformed due to the heat or the like.

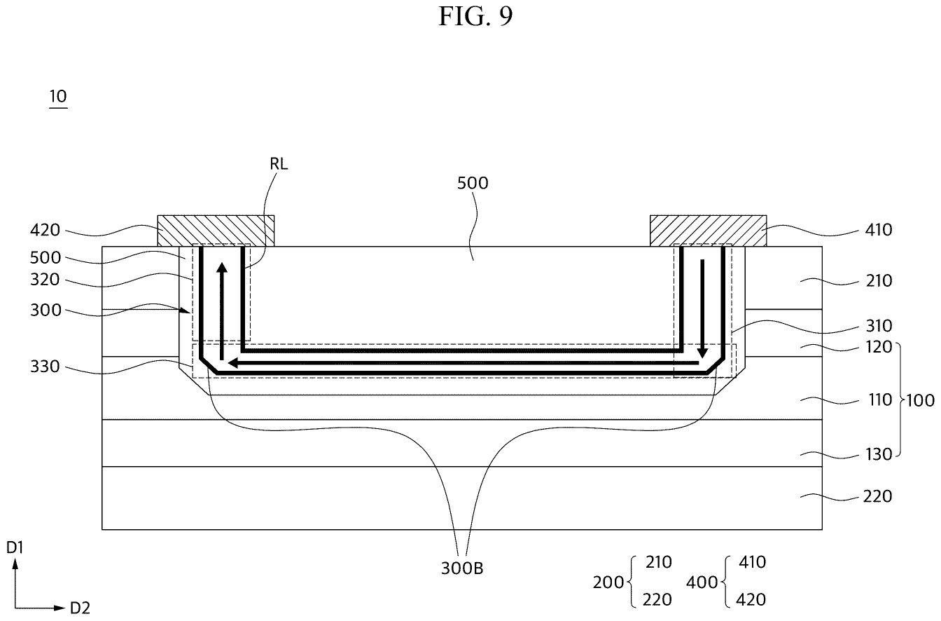

Referring to FIG. 9, while surrounding a portion of the lower surface 410BS of the first pad and the lower surface 420BS of the second pad, a portion of the heat emission layer 500 may disposed at and fill the portion of the area of the core substrate 100, which is surrounded by the first area 310, the second are 320, and the third area 330 of the optical waveguide 300. In some example embodiments, while surrounding a portion of the lower surface 410BS of the first pad and the lower surface 420BS of the second pad, another portion of the heat emission layer 500 may disposed at the portion of the area of the core substrate 100, which surrounds the first area 310, the second are 320, and the third area 330, and surrounds the outer wall of the optical waveguide 300. Through this, the structure of the optical waveguide 300 may be limited and/or prevented from being deformed due to the heat or the like.

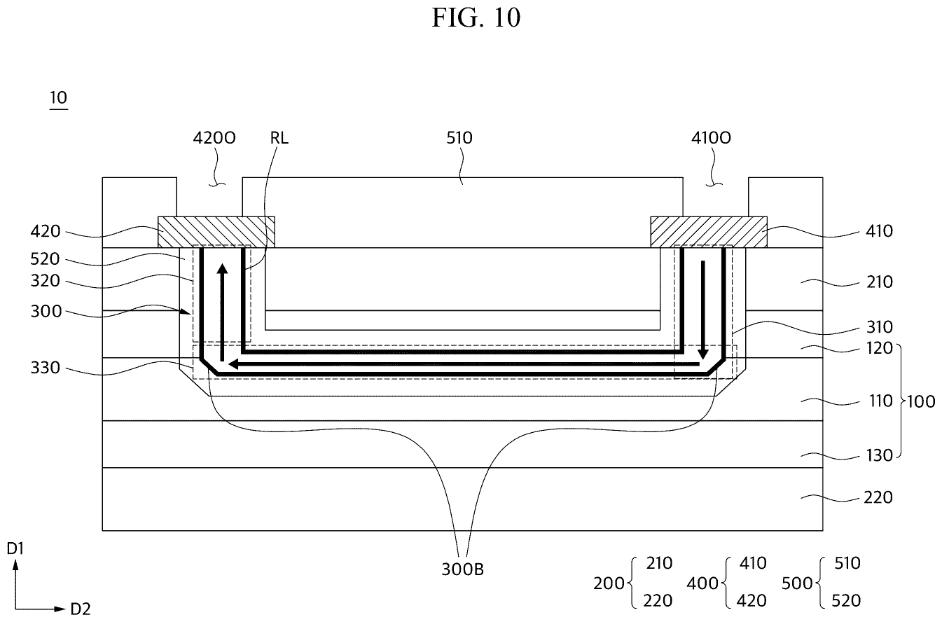

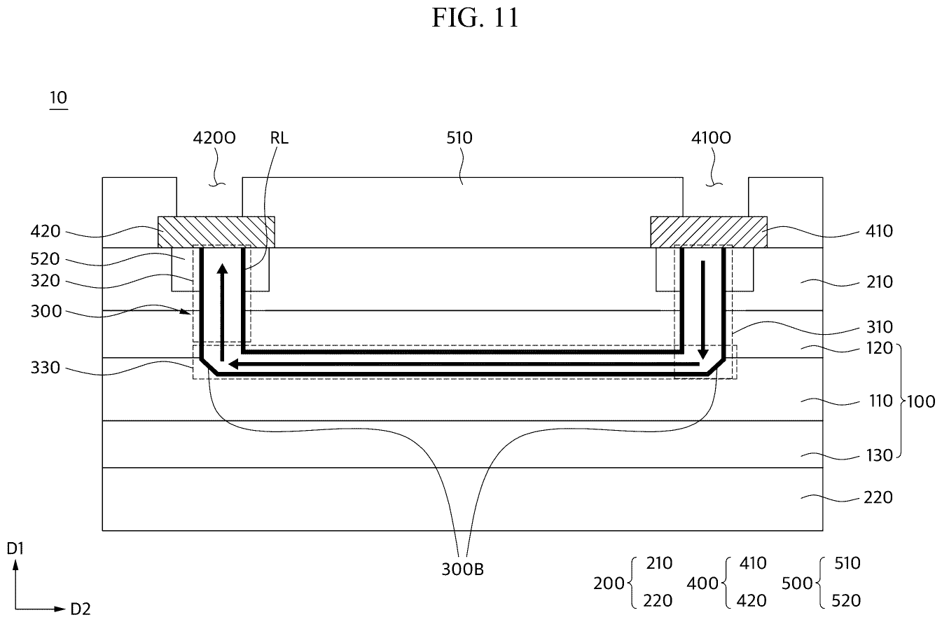

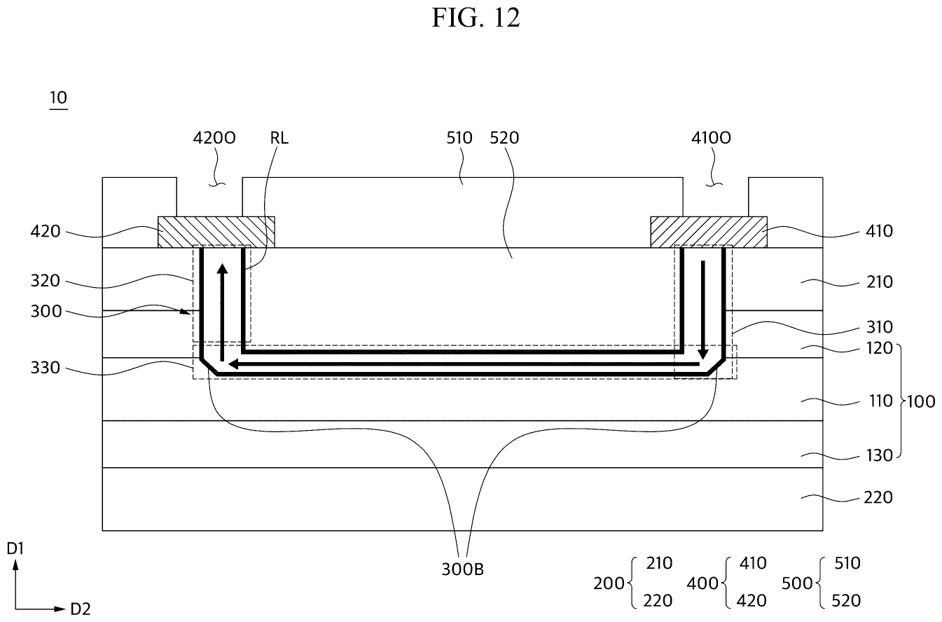

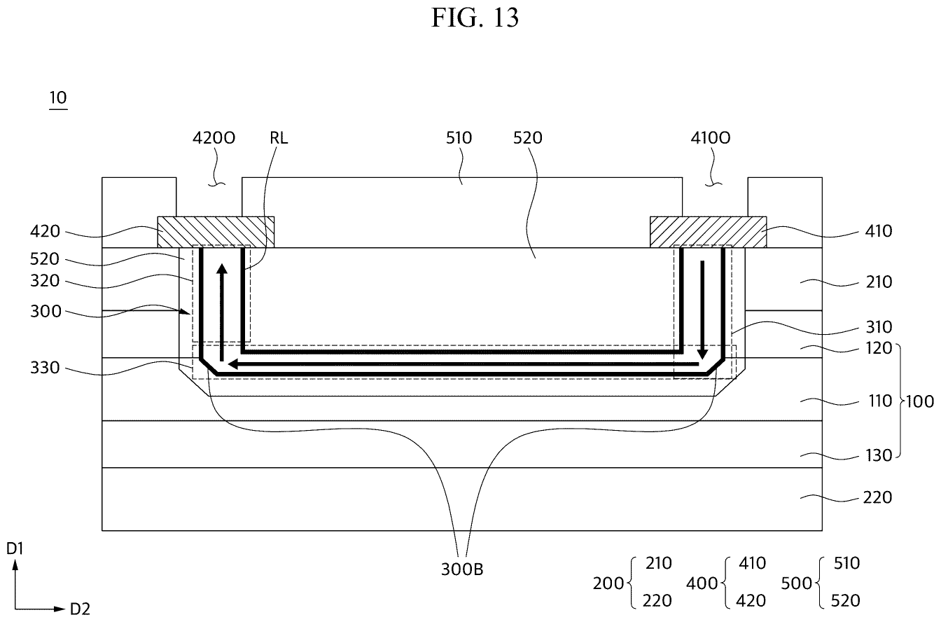

FIGS. 10 through 13 are cross-sectional diagrams illustrating disposition of the heat emission layer 500 according to some example embodiments of the present disclosure.

In some example embodiments, the heat emission layer 500 may include one or more of a first heat emission layer 510 surrounding a portion of the upper surface 410US of a first pad and the upper surface 420US of a second pad and a second heat emission layer 520 surrounding a portion of the lower surface 410BS of the first pad and the lower surface 420BS of the second pad. In some example embodiments, the above description of the heat emission layer 500 with reference to FIGS. 1 through 5 may be referenced for the first heat emission layer 510 unless contradictory to another description and thus may be omitted from the following for the sake of brevity. In some example embodiments, the above description of the heat emission layer 500 with reference to FIGS. 6 through 9 may be referenced for the second heat emission layer 520 unless contradictory to another description and thus may be omitted from the following for the sake of brevity.

In some example embodiments as shown in FIGS. 10-13 for example, the first heat emission layer 510 may include the first exposure part 410O which is formed by penetrating the first heat emission layer 510 and exposes at least a portion of the upper surface 410US of the first pad and the second exposure part 420O which is formed by penetrating the first heat emission layer 510 and exposes at least a portion of the upper surface 420US of the second pad. In some example embodiments a width of the first exposure part 410O along the second direction D2 may gradually increase away from the first pad 410 in the first direction D1, and in some example embodiments a width of the second exposure part 420O along the second direction D2 may gradually increase away from the second pad 420 in the first direction D1 (see FIG. 2).

In some example embodiments, the second heat emission layer 520 may surround at least a portion of an outer wall of the optical waveguide 300. Through this, a structure of the optical waveguide 300 may be limited and/or prevented from being deformed due to heat or the like.

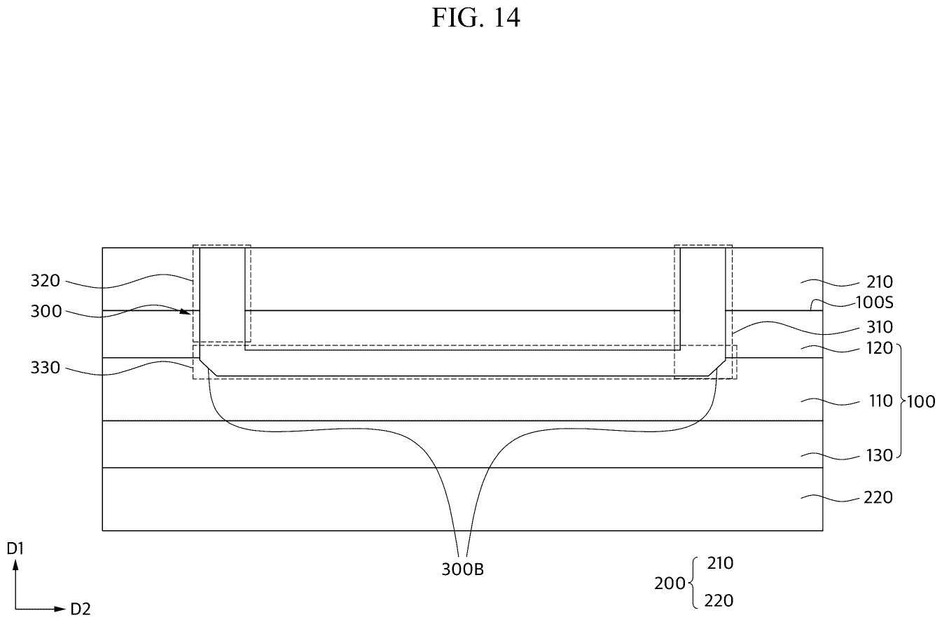

FIGS. 14 through 19 each are cross-sectional diagrams illustrating a process of manufacturing the printed circuit board 10 according to some example embodiments of the present disclosure. The above description made with reference to FIGS. 1 through 13 may be referenced for the following description unless contradictory thereto and thus may be omitted from the following for the sake of brevity.

Referring to FIG. 14, in some example embodiments, a method of manufacturing the printed circuit board 10 may include forming the optical waveguide 300 to the core substrate 100 including the core layer 110, the upper glass layer 120 disposed on a surface of the core layer 110, and the lower glass layer 130 disposed on another surface of the core layer 110. In some example embodiments, the optical waveguide 300 may be formed by processing a portion of the core substrate 100 through drilling, laser work, or the like. In some example embodiments, the method of manufacturing the printed circuit board 10 may include forming the optical waveguide 300 so that at least a portion thereof is disposed between the upper glass layer 120 and the lower glass layer 130. In some example embodiments, the method of manufacturing the printed circuit board 10 may include forming the insulation layer 200 on the core substrate 100. In some example embodiments, the method of manufacturing the printed circuit board 10 may include forming the first insulation layer 210 disposed on a surface of the core substrate 100 and the second insulation layer 220 disposed on another surface of the core substrate 100.

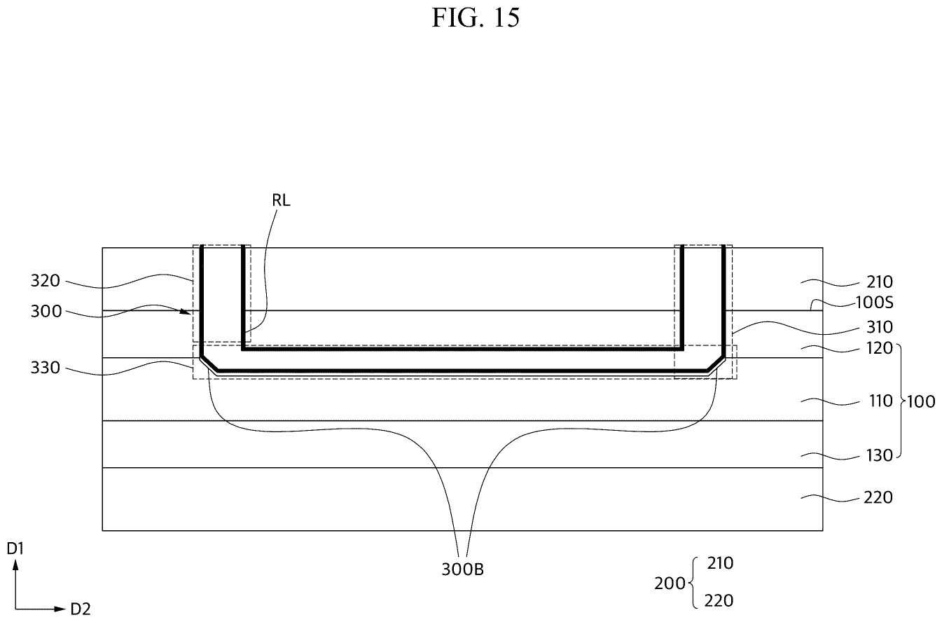

Referring to FIG. 15, in some example embodiments, the method of manufacturing the printed circuit board 10 may include forming the reflection layer RL to at least a portion of an inner wall of the optical waveguide 300. In some example embodiments, the reflection layer RL may be formed through deposition. For example, the deposition may be performed as one or more of chemical vapor deposition (CVD), physics vapor deposition (PVD), atomic layer deposition (ALD), and the like.

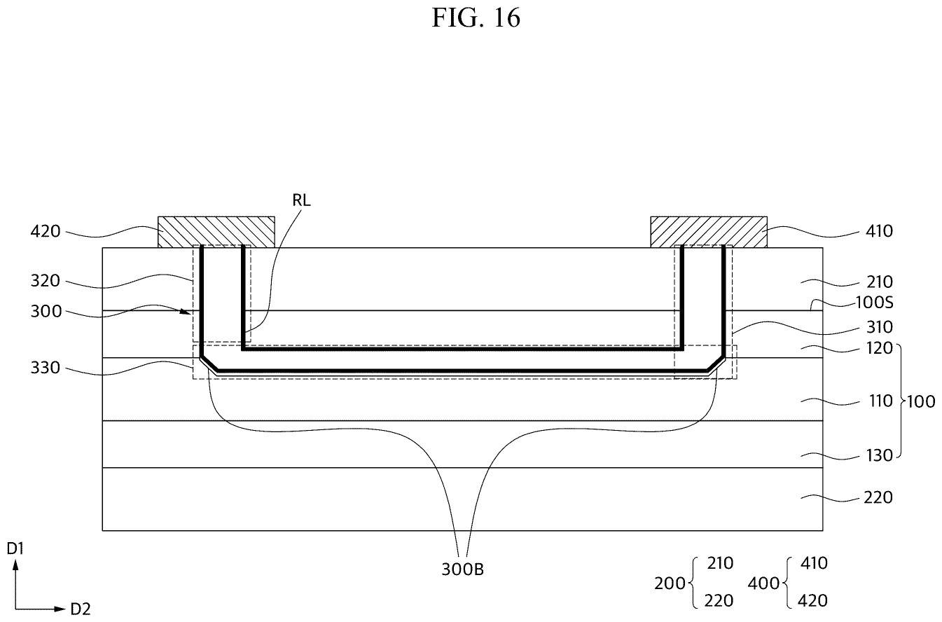

Referring to FIG. 16, in some example embodiments, the method of manufacturing the printed circuit board 10 may include forming the pad 400 on the core substrate 100. In some example embodiments, the method of manufacturing the printed circuit board 10 may include forming the first pad 410 on the core substrate 100 so that the first pad 410 is connected to the optical waveguide 300 and may include forming the second pad 420 on the core substrate 100 so that the second pad 420 is spaced apart from the first pad 410 and connected to the optical waveguide 300. In some example embodiments, the first pad 410 and the second pad 420 may be formed through a photo process or the like.

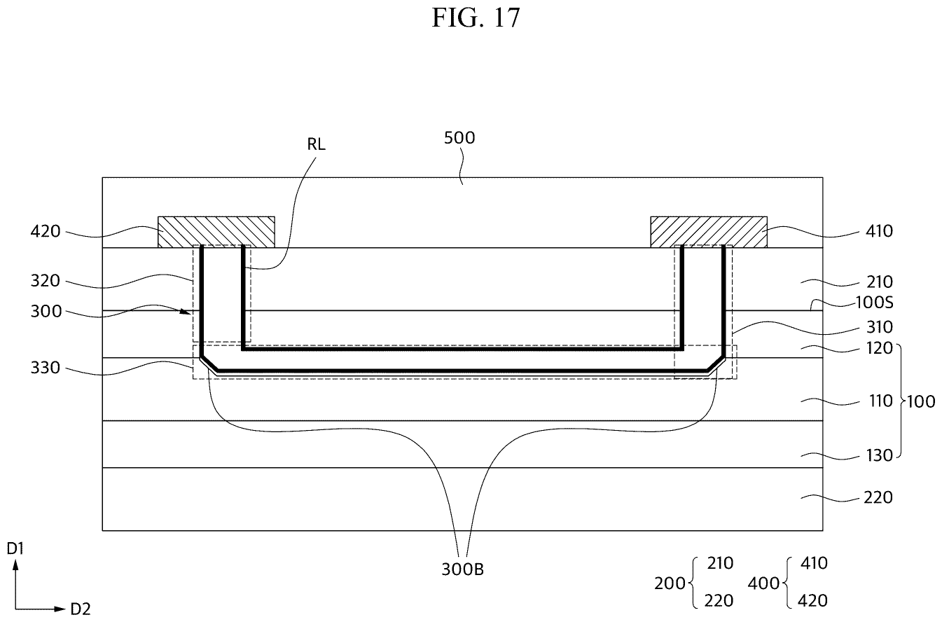

Referring to FIG. 17, in some example embodiments, the method of manufacturing the printed circuit board 10 may include forming the heat emission layer 500 so that the heat emission layer 500 is in contact with at least a portion of the pad 400. In some example embodiments, a heat emission composition including a resin component and a filler component may cure, so that the heat emission layer 500 may be formed. In some example embodiments, the heat emission layer 500 may be formed by applying the heat emission composition so that the heat emission composition is in contact with the at least a portion of the pad 400 and curing the applied heat emission composition.

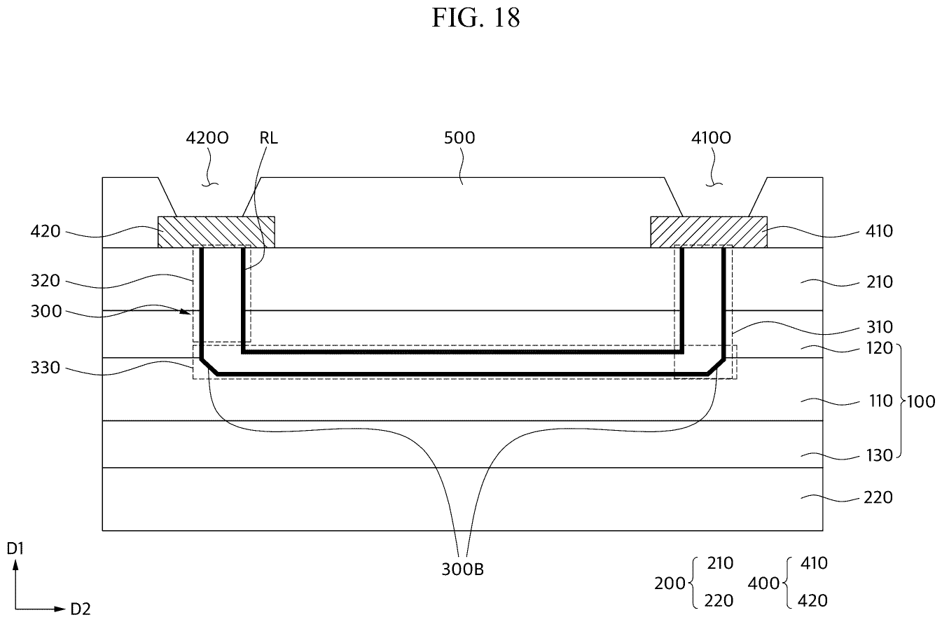

Referring to FIG. 18, in some example embodiments, the method of manufacturing the printed circuit board 10 may include forming the first exposure part 410O which penetrates the heat emission layer 500 and exposes at least a portion of the upper surface 410US of the first pad and the second exposure part 420O which penetrates the heat emission layer 500 and exposes at least a portion of the upper surface 420US of the second pad. In some example embodiments, with the method of manufacturing the printed circuit board 10, the first exposure part 410O may be formed so that a width thereof along the second direction D2 may gradually increase away from the first pad 410 in the first direction D1, and the second exposure part 420O may be formed so that a width thereof along the second direction D2 may gradually increase away from the second pad 420 in the first direction D1.

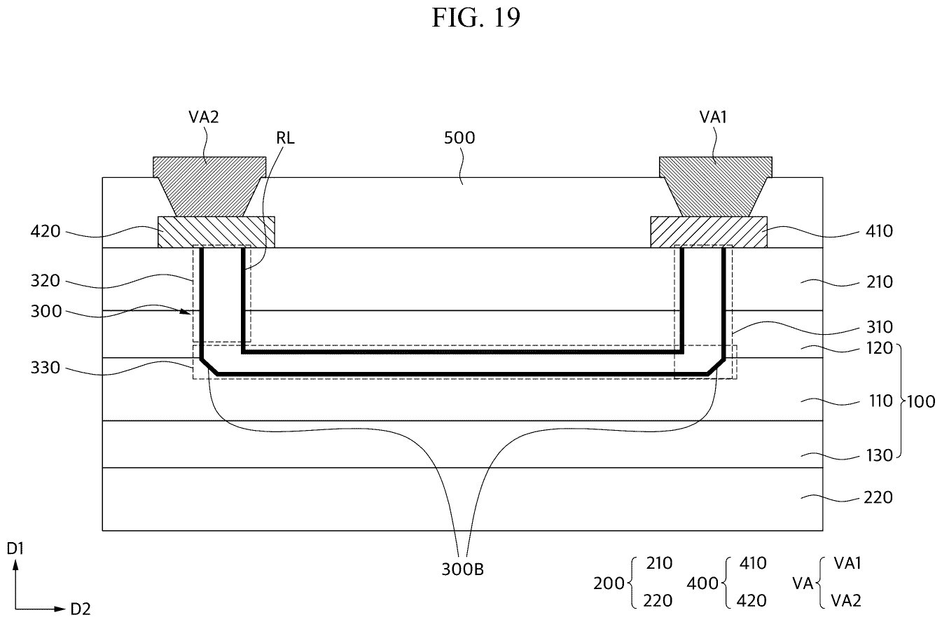

Referring to FIG. 19, in some example embodiments, the method of manufacturing the printed circuit board 10 may include forming the via VA electrically connected to the pad 400. In some example embodiments, the method of manufacturing the printed circuit board 10 may include forming the first via VA1 disposed to the first exposure part 410O and electrically connected to the first pad 410 and the second via VA2 disposed to the second exposure part 420O and electrically connected to the second pad 420.

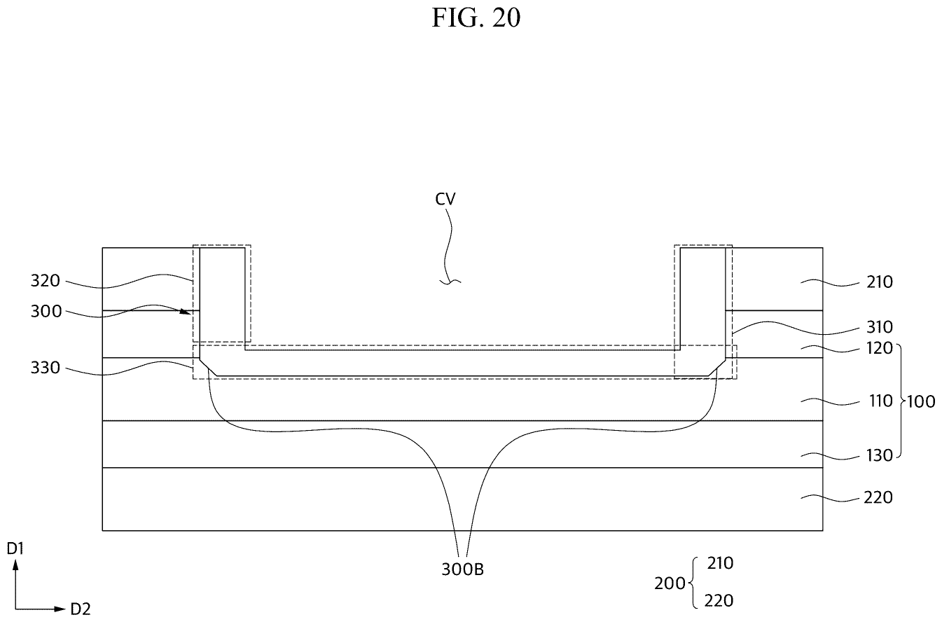

FIGS. 20 through 25 are cross-sectional diagrams illustrating a process of manufacturing the printed circuit board 10 with different disposition of the heat emission layer 500 according to some example embodiments of the present disclosure. The above description with reference to FIGS. 1 through 19 may be referenced for the following description unless contradictory thereto and thus may be omitted from the following for the sake of brevity.

Referring to FIG. 20, in some example embodiments, the method of manufacturing the printed circuit board 10 may include forming a cavity CV at a portion of the core substrate 100. In some example embodiments, the cavity CV may be processed and formed through drilling, laser work, or the like.

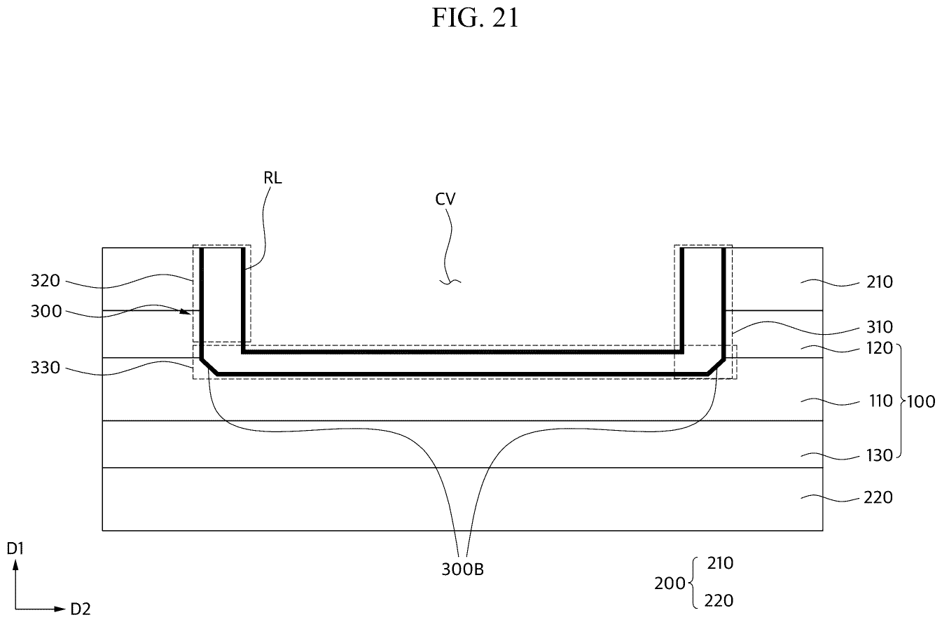

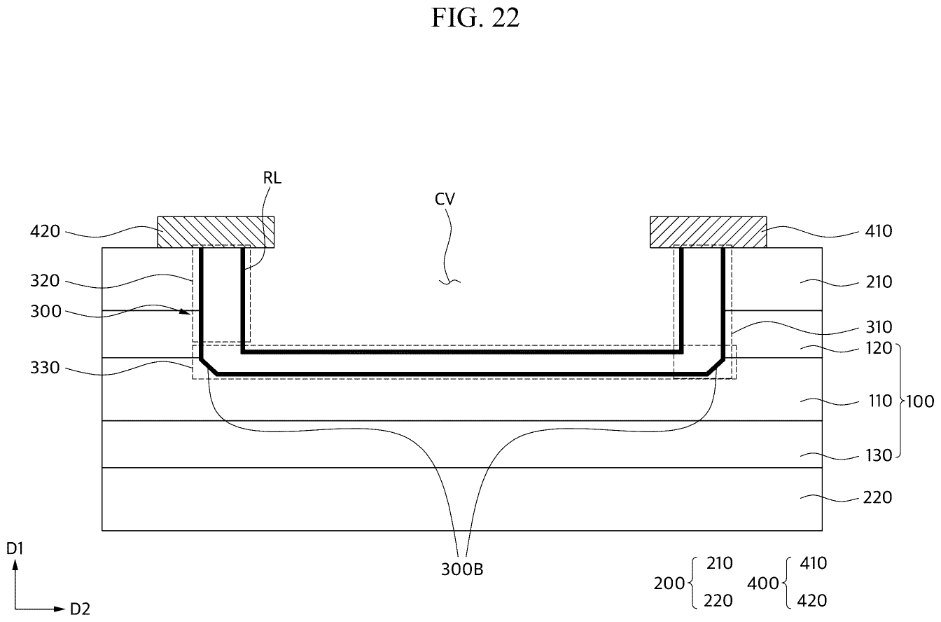

The above descriptions for FIGS. 15 and 16 may be referenced for descriptions for FIGS. 21 and 22. Referring to FIG. 21, in some example embodiments, the method of manufacturing the printed circuit board 10 may include forming the reflection layer RL to at least a portion of an inner wall of the optical waveguide 300. Referring to FIG. 22, in some example embodiments, the method of manufacturing the printed circuit board 10 may include forming the first pad 410 on the core substrate 100 so that the first pad 410 is connected to the optical waveguide 300 and may include forming the second pad 420 on the core substrate 100 so that the second pad 420 is spaced apart from the first pad 410 and connected to the optical waveguide 300. A shape of the first pad 410 and the second pad 420 shown in FIG. 22 may be naturally obtained during the formation process. However, the shape of the first pad 410 and the second pad 420 are not limited thereto.

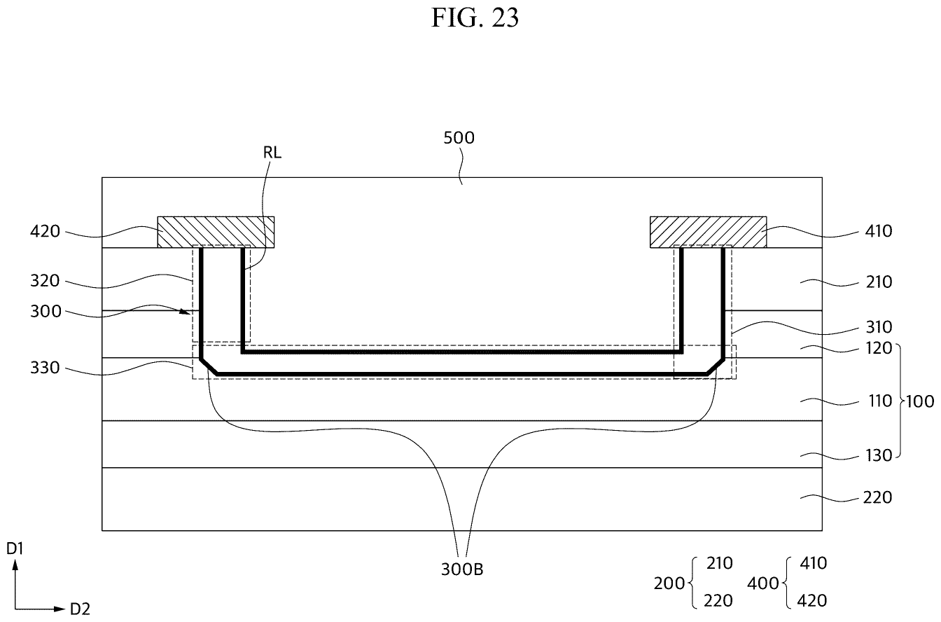

Referring to FIG. 23, in some example embodiments, the method of manufacturing the printed circuit board 10 may include forming the heat emission layer 500 so that the heat emission layer 500 is in contact with at least a portion of the pad 400. In some example embodiments, the heat emission layer 500 may be formed while filling at least a portion of the cavity CV.

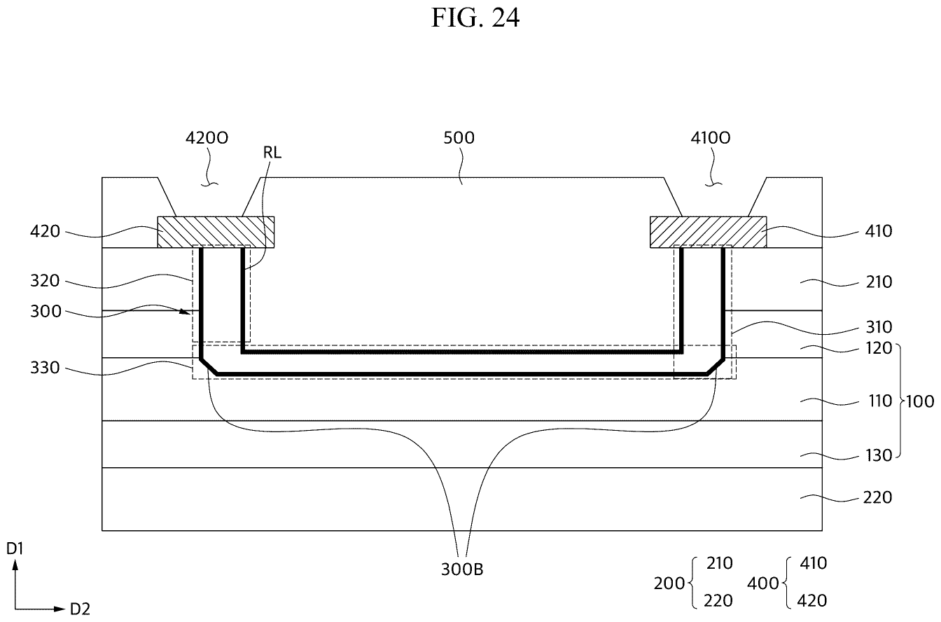

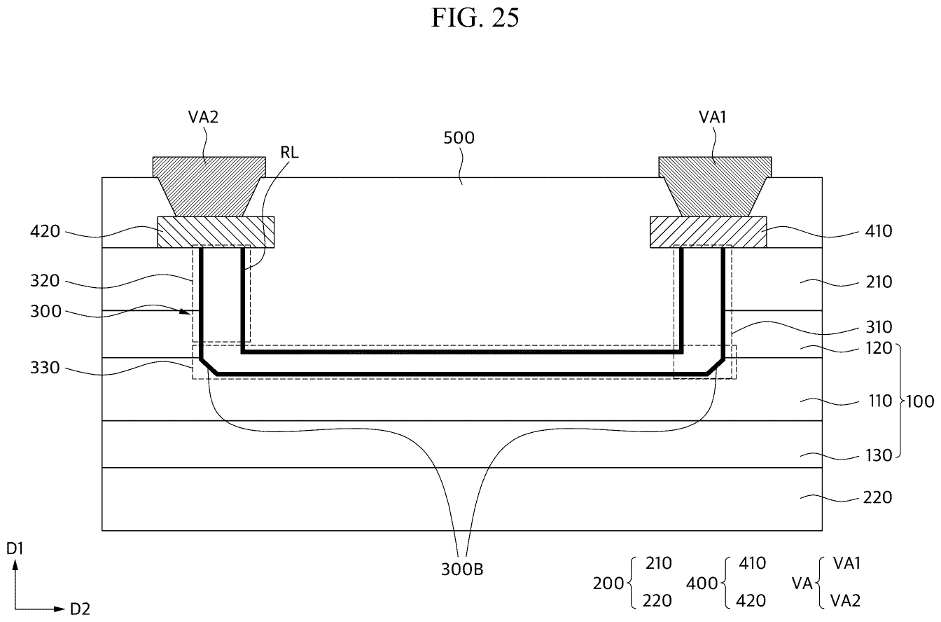

The above descriptions for FIGS. 18 and 19 may be referenced for descriptions for FIGS. 24 and 25. Referring to FIG. 24, in some example embodiments, the method of manufacturing the printed circuit board 10 may include forming the first exposure part 410O which penetrates the heat emission layer 500 and exposes at least a portion of the upper surface 410US of the first pad and the second exposure part 420O which penetrates the heat emission layer 500 and exposes at least a portion of the upper surface 420US of the second pad. Referring to FIG. 25, in some example embodiments, the method of manufacturing the printed circuit board 10 may include forming the first via VA1 disposed to the first exposure part 410O and electrically connected to the first pad 410 and the second via VA2 disposed to the second exposure part 420O and electrically connected to the second pad 420.

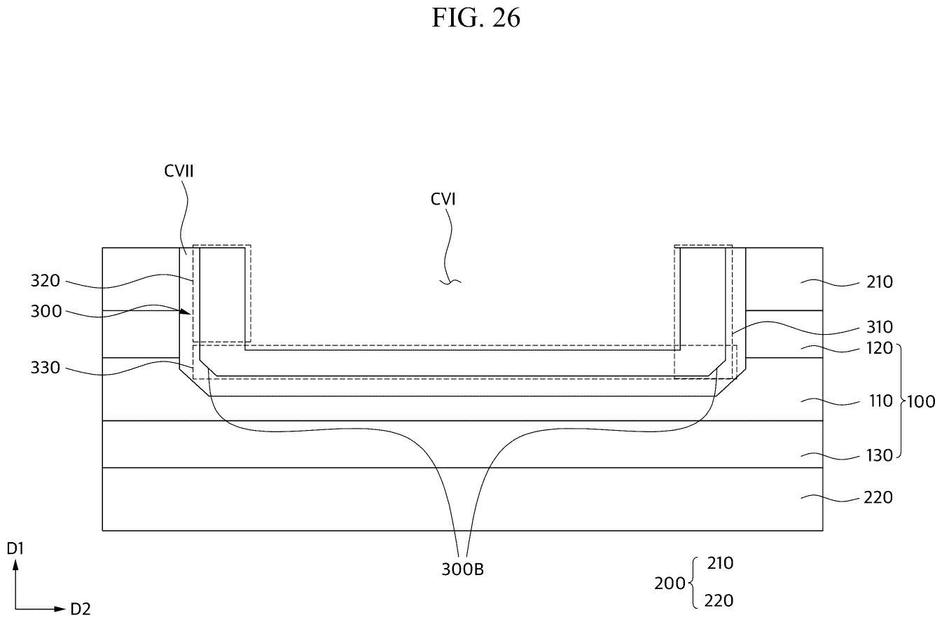

FIGS. 26 through 31 are cross-sectional diagrams illustrating a process of manufacturing the printed circuit board 10 with different disposition of the heat emission layer 500 according to some example embodiments of the present disclosure.

Referring to FIG. 26, in some example embodiments, a method of manufacturing the printed circuit board 10 may include forming cavities to a portion of the core substrate 100. In some example embodiments, the method of manufacturing the printed circuit board 10 may include forming a first cavity CVI to a portion of an area of the core substrate 100 which is surrounded by the first area 310, the second area 320, and the third area 330 of the optical waveguide 300 and a second cavity CVII to a portion of an area of the core substrate 100 which surrounds the first area 310, the second area 320, and the third area 330. For example, the first cavity CVI may be disposed in between the first area 310, the second area 320 and the third area 330, and the second cavity CVII may be disposed between the core substrate 100 and the first area 310, the second area 320 and the third area 330, respectively. In some example embodiments, the first cavity CVI and the second cavity CVII may be processed and formed through drilling, laser work, or the like.

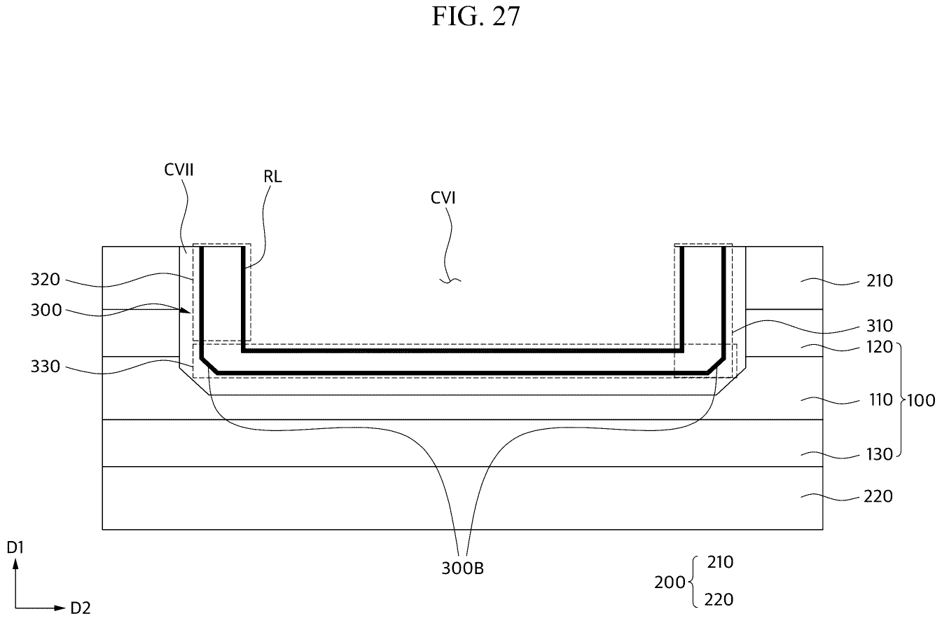

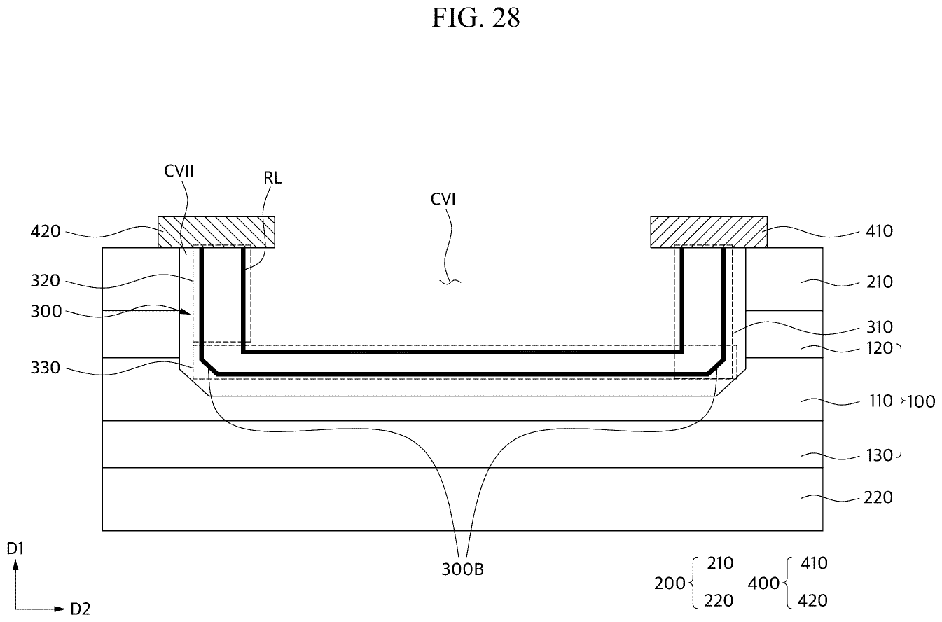

The above descriptions for FIGS. 15 and 16 or the above descriptions for FIGS. 21 and 22 may be referenced for descriptions for FIGS. 27 and 28 and thus may be omitted from the following for the sake of brevity. Referring to FIG. 27, in some example embodiments, the method of manufacturing the printed circuit board 10 may include forming the reflection layer RL to at least a portion of an inner wall of the optical waveguide 300. Referring to FIG. 28, in some example embodiments, the method of manufacturing the printed circuit board 10 may include forming the first pad 410 on the core substrate 100 so that the first pad 410 is connected to the optical waveguide 300 and may include forming the second pad 420 on the core substrate 100 so that the second pad 420 is spaced apart from the first pad 410 and connected to the optical waveguide 300. A shape of the first pad 410 and the second pad 420 shown in FIG. 28 may be naturally obtained during the formation process. However, the shape of the first pad 410 and the second pad 420 are not limited thereto.

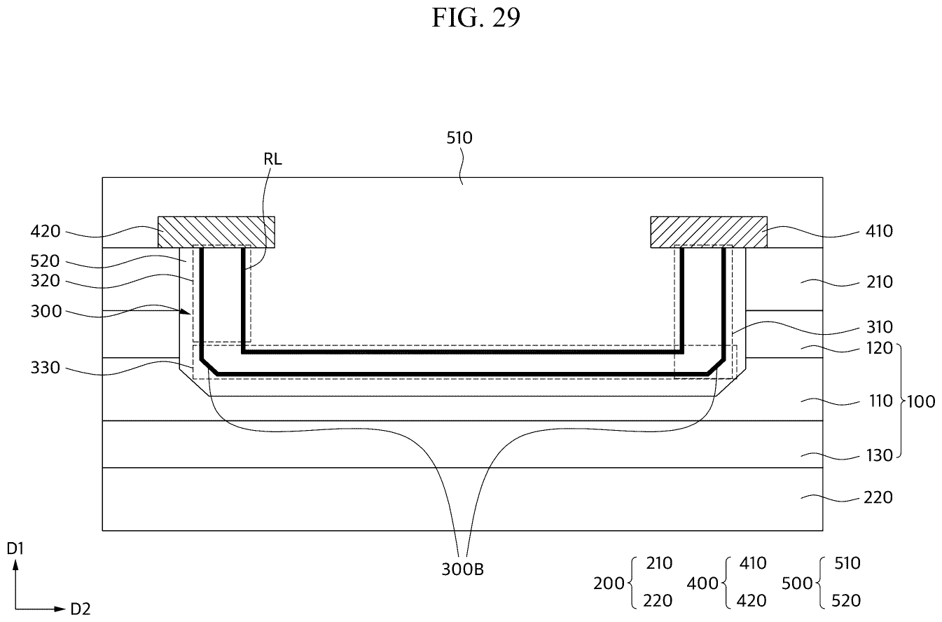

Referring to FIG. 29, in some example embodiments, the method of manufacturing the printed circuit board 10 may include forming the heat emission layer 500 so that the heat emission layer 500 is in contact with at least a portion of the pad 400. In some example embodiments, the heat emission layer 500 may be formed while filling at least a portion of each of the first cavity CVI and the second cavity CVII. In some example embodiments, the method of manufacturing the printed circuit board 10 may include forming the first heat emission layer 510 so that the first heat emission layer 510 surrounds a portion of the upper surface 410US of the first pad and the upper surface 420US of the second pad and forming the second heat emission layer 520 so that the second heat emission layer 520 surrounds a portion of the lower surface 410BS of the first pad and the lower surface 420BS of the second pad by forming and filling the at least a portion of each of the first cavity CV1 and the second cavity CVII.

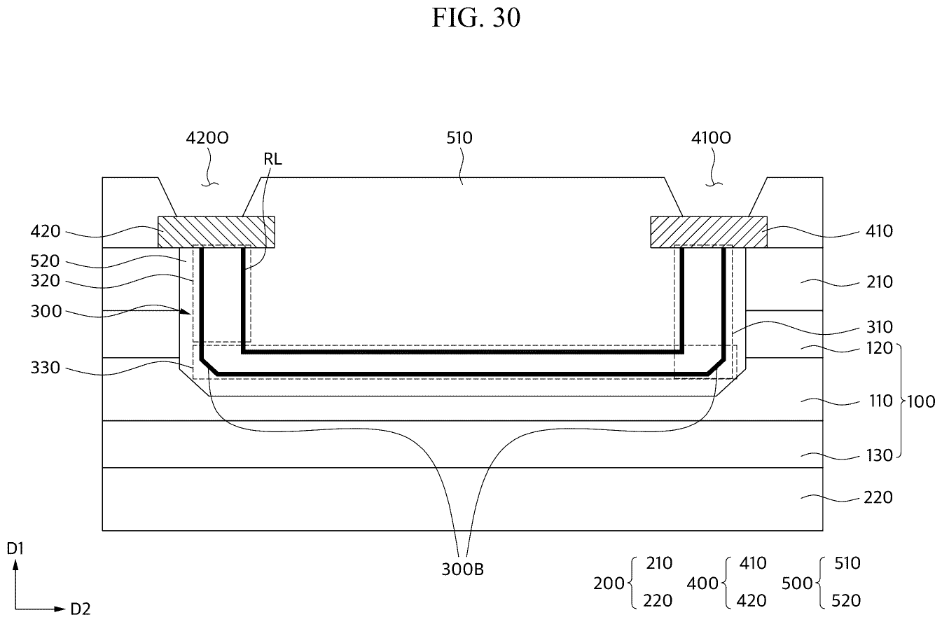

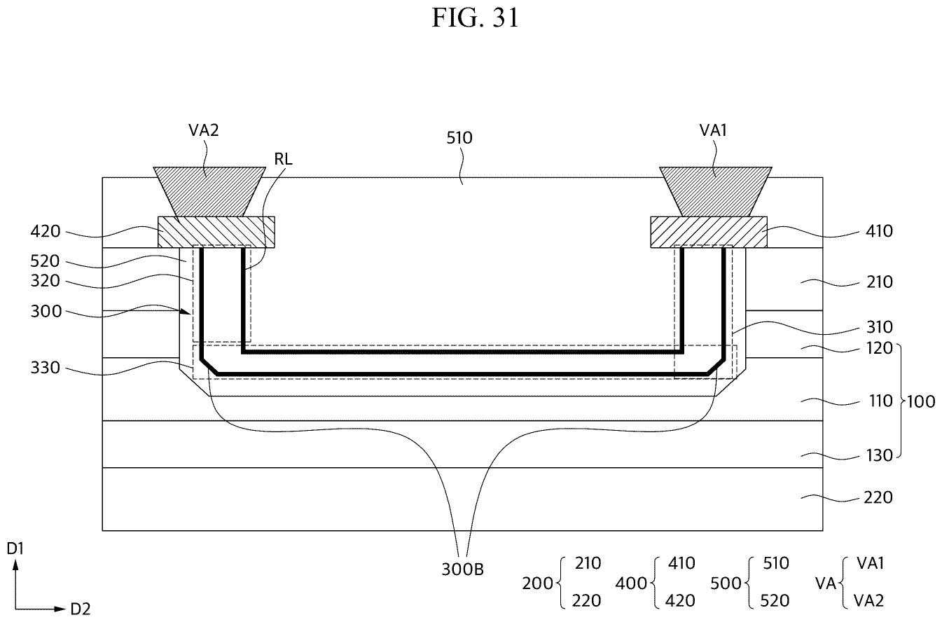

The above descriptions for FIGS. 18 and 19 or the above descriptions for FIGS. 24 and 25 may be referenced for descriptions for FIGS. 30 and 31 and thus may be omitted from the following for the sake of brevity. Referring to FIG. 30, in an some example embodiments, the method of manufacturing the printed circuit board 10 may include forming the first exposure part 410O which penetrates the heat emission layer 500 and exposes at least a portion of the upper surface 410US of the first pad and the second exposure part 420O which penetrates the heat emission layer 500 and exposes at least a portion of the upper surface 420US of the second pad. Referring to FIG. 31, in some example embodiments, the method of manufacturing the printed circuit board 10 may include forming the first via VA1 disposed at the first exposure part 410O and electrically connected to the first pad 410 and the second via VA2 disposed at the second exposure part 420O and electrically connected to the second pad 420.

The some example embodiments have been described with reference to the accompanying drawings above. However, the present disclosure is not limited to the above some example embodiments and may be manufactured in various forms different from each other. Those skilled in the art to which the present disclosure belongs may understand that some other example embodiments may be implemented without changing the technical spirit or the characteristics of the present disclosure. Therefore, in all aspects, the above-described some example embodiments should be understood as mere examples and not as being limitative.

What is claimed is:

1. A printed circuit board comprising:
a core substrate comprising a core layer, an upper glass layer on a surface of the core layer, and a lower glass layer on another surface of the core layer;
an optical waveguide including at least a portion between the upper glass layer and the lower glass layer, the optical waveguide comprising a reflection layer on at least a portion of an inner wall of the optical waveguide;
a first pad on the core substrate, the first pad being connected to the optical waveguide;
a second pad on the core substrate, the second pad spaced apart from the first pad, and the second pad being connected to the optical waveguide; and
a heat emission layer contacting at least a portion of each of the first pad and the second pad.

2. The printed circuit board of claim 1, wherein when viewed in a first direction perpendicular to an upper surface of the core substrate, the optical waveguide further comprises:
a first area overlapping the first pad;
a second area overlapping the second pad; and
a third area connecting the first area and the second area.

3. The printed circuit board of claim 2, wherein the first area and the second area are side by side and extend parallel to the first direction.

4. The printed circuit board of claim 2, wherein the third area extends parallel to a second direction, the second direction being parallel to the upper surface of the core substrate, and the second direction crossing the first direction.

5. The printed circuit board of claim 4, wherein the optical waveguide further comprises:
a first bent portion between the first area and the third area; and
a second bent portion between the second area and the third area.

6. The printed circuit board of claim 1, wherein the at least a portion of the inner wall of the optical waveguide has an average surface roughness less than or equal to 50 nanometers.

7. The printed circuit board of claim 1, wherein a total reflectance of the at least a portion of the inner wall of the optical waveguide for an ultraviolet ray is less than or equal to 10%.

8. The printed circuit board of claim 1, wherein a specular reflectance of the at least a portion of the inner wall of the optical waveguide for an ultraviolet ray is less than or equal to 10%.

9. The printed circuit board of claim 1, wherein a diffuse reflectance of the at least a portion of the inner wall of the optical waveguide for an ultraviolet ray is less than or equal to 3%.

10. The printed circuit board of claim 1, wherein the first pad and the second pad are on an identical plane.

11. The printed circuit board of claim 1, wherein the heat emission layer comprises:
a resin component; and
a filler component dispersed in the resin component.

12. The printed circuit board of claim 1, wherein the heat emission layer has a heat conductivity greater than or equal to 0.5 watts per meter-Kelvin (W/m·K) measured according to ASTM D 5470 standard.

13. The printed circuit board of claim 1, wherein the heat emission layer comprises at least one of:
a first heat emission layer surrounding at least a portion of an upper surface of the first pad and at least a portion of an upper surface of the second pad; and
a second heat emission layer surrounding at least a portion of a lower surface of the first pad and at least a portion of a lower surface of the second pad.

14. The printed circuit board of claim 13, wherein the first heat emission layer defines therein
a first exposure part penetrating the first heat emission layer and exposing at least a portion of the upper surface of the first pad; and
a second exposure part penetrating the first heat emission layer and exposing at least a portion of the upper surface of the second pad.

15. The printed circuit board of claim 14, wherein
the first exposure part has a first width that gradually increases away from the first pad in a first direction perpendicular to a surface of the core substrate, and
the second exposure part has a second width that gradually increases away from the second pad in the first direction.

16. The printed circuit board of claim 13, wherein the second heat emission layer is configured to surround the at least a portion of the inner wall of the optical waveguide.

17. The printed circuit board of claim 1, wherein the core layer comprises a dielectric.

18. A printed circuit board comprising:
a core substrate comprising a core layer, an upper glass layer on a surface of the core layer, and a lower glass layer on another surface of the core layer, the core layer comprising a dielectric;
an optical waveguide including at least a portion between the upper glass layer and the lower glass layer, the optical waveguide comprising a reflection layer on at least a portion of an inner wall of the optical waveguide;
a first pad on the core substrate, the first pad being connected to the optical waveguide;
a second pad on the core substrate, the second pad being spaced apart from the first pad, and the second pad being connected to the optical waveguide; and
a heat emission layer contacting at least a portion of each of the first pad and the second pad,
wherein the at least a portion of the inner wall of the optical waveguide has an average surface roughness less than or equal to 50 nanometers.

19. The printed circuit board of claim 18, wherein a transmittance of each of the upper glass layer and the lower glass layer for an ultraviolet ray is greater than or equal to 80%.

20. A printed circuit board comprising:
a core substrate comprising a core layer, an upper glass layer on a surface of the core layer, and a lower glass layer on another surface of the core layer, the core layer comprising a dielectric;
an optical waveguide including at least a portion between the upper glass layer and the lower glass layer, the optical waveguide comprising a reflection layer on at least a portion of an inner wall of the optical waveguide;
a first pad on the core substrate, the first pad being connected to the optical waveguide;
a second pad on the core substrate, the second pad being spaced apart from the first pad, and the second pad being connected to the optical waveguide; and
a heat emission layer contacting at least a portion of each of the first pad and the second pad,
wherein when viewed in a first direction perpendicular to an upper surface of the core substrate, the optical waveguide comprises
a first area overlapping the first pad,
a second area overlapping the second pad, and
a third area connecting the first area and the second area, and
wherein
the first area and the second area are side by side and extend parallel to the first direction,
the third area extends parallel to a second direction, the second direction is parallel to the surface of the core substrate and the second direction crosses the first direction,
the at least a portion of the inner wall of the optical waveguide has an average surface roughness less than or equal to 50 nanometers,
a total reflectance of the at least a portion of the inner wall of the optical waveguide for an ultraviolet ray is less than or equal to 10%,
a specular reflectance of the at least a portion of the inner wall of the optical waveguide for the ultraviolet ray is less than or equal to 10%, and
a diffuse reflectance of the at least a portion of the inner wall of the optical waveguide for the ultraviolet ray is less than or equal to 3%.
